(19) United States
(12) Patent Application Publication
(10) Pub. No.: US 2015/0255243 A1
(43) Pub. Date: Sep. 10, 2015

(54) GRAZING ANGLE PLASMA PROCESSING FOR MODIFYING A SUBSTRATE SURFACE

(71) Applicant: Applied Materials, Inc., Santa Clara, CA (US)

(72) Inventors: Ludovic GODET, Sunnyvale, CA (US); Ellie Y. YIEH, San Jose, CA (US); Srinivas D. NEMANI, Sunnyvale, CA (US); Gary E. DICKERSON, Gloucester, MA (US); Svetlana B. RADOVANOV, Brookline, MA (US); Adam BRAND, Palo Alto, CA (US)

(21) Appl. No.: 14/641,071

(22) Filed: Mar. 6, 2015

Related U.S. Application Data
(60) Provisional application No. 61/949,841, filed on Mar. 7, 2014.
(60) Provisional application No. 61/989,370, filed on May 6, 2014.

(51) Int. Cl. H01J 37/147; H01J 37/08; H01J 37/32

(52) U.S. Cl. CPC H01J 37/1477; H01J 37/32733; H01J 37/3211; H01J 37/32697; H01J 37/08; H01J 2237/334; H01J 2237/1501; H01J 2237/1512

(57) ABSTRACT

Embodiments of the disclosure provide apparatus and methods for modifying a surface of a substrate using a plasma modification process. In one embodiment, a process generally includes the removal and/or redistribution of a portion of an exposed surface of the substrate by use of an energetic particle beam while the substrate is disposed within a particle beam modification apparatus. Embodiments may also provide a plasma modification process that includes one or more pre-planarization processing steps and/or one or more post-planarization processing steps that are all performed within one processing system. Some embodiments may provide an apparatus and methods for planarizing a surface of a substrate by performing all of the plasma modification processes within either the same processing chamber, the same processing system or within processing chambers found in two or more processing systems.

### CROSS-REFERENCE TO RELATED APPLICATIONS

This application claims benefit of both U.S. provisional patent application Ser. No. 61/949,841, filed Mar. 7, 2014, and U.S. provisional patent application Ser. No. 61/989,370, filed May 6, 2014. Both cases in their entirety are hereby incorporated herein by reference.

### BACKGROUND OF THE INVENTION

1. Field of the Invention

Embodiments of the disclosure provided herein generally relate to apparatus and methods for planarizing a non-uniform surface topography found on a surface of a substrate.

2. Description of the Related Art

Integrated circuits are typically formed on substrates, particularly silicon wafers, by the sequential deposition of conductive, semiconducting or insulating layers. After each layer is deposited, it is etched to create circuitry features. As a series of layers are sequentially deposited and etched, the outer or uppermost surface of the substrate, i.e., the exposed surface of the substrate, becomes increasingly non-planar. FIG. 1A is a cross-sectional view of a device structure 100 formed on a substrate 112 that has a non-planar surface 120. The device structure 100 may include a patterned layer 114, which is formed on a surface of the substrate 112, and a deposited layer 116 that is formed over the patterned layer 114 and the substrate 112. Due to the absence of material in various regions of the patterned layer 114, the upper surface of the deposited layer 116 will contain features 121 that form part of the non-planar surface 120. This non-planar surface presents problems in the photolithographic steps of the integrated circuit fabrication process. Therefore, there is a need to periodically planarize the substrate surface to provide a planar surface.

Chemical mechanical polishing is one accepted method of planarization. This planarization method typically requires that the substrate be mounted on a carrier or polishing head with the exposed surface of the substrate being placed against a rotating polishing pad or moving polishing belt that has a polishing slurry disposed thereon. The carrier head provides a controllable motion relative to the polishing pad and applies a load (i.e., pressure) to the substrate to cause the removal of a portion of an exposed layer on the substrate by mechanical action created between the substrate and the polishing pad. The polishing slurry, which will generally include at least one chemically-reactive agent (e.g., acids, bases or even deionized water for oxide polishing) and abrasive particles (e.g., silicon dioxide for oxide polishing), is supplied to the surface of the polishing pad and substrate during the CMP process to help remove a portion of the substrate by mechanical and chemical action.

In applying conventional planarization techniques, such as CMP, it is extremely difficult to achieve a high degree of surface uniformity, particularly across a surface extending from a dense array of features, for example copper lines, bordered by an open field. In planarizing the substrate surface using a CMP process, undesirable erosion and dishing typically occur, decreasing the degree of surface uniformity or planarity, and challenging the depth of focus limitations of conventional photolithographic techniques, particular with respect to achieving submicron dimensions, such as about 0.25 micron and below. Dishing is defined as a difference in height between the height of the sidewalls of a feature formed in a dielectric layer (e.g., oxide layer) and the material disposed within the feature (e.g., copper (Cu) (interconnect applications), silicon dioxide (STI applications)) within the dense array. Erosion is defined as the height differential between the oxide in the open field and the height of the oxide within the dense array. Dishing and erosion formation are the most important parameters in evaluating the effectiveness of a planarization process. FIG. 1B is a cross-sectional view of the device structure 100, shown in FIG. 1A, after a CMP planarization process has been performed, wherein the polished device structure contains a planarized surface 119 and a feature 117 that has a dishing type defect. It remains desirable to have a process of planarization where dishing and erosion are decreased or removed entirely.

The demand for planarization processes that can be performed on ultrathin layers, mechanically fragile layers (e.g., low-k materials and structures) and on layers that contain toxic elements (e.g., arsenic (As)) has increased over the years, due to the shrinkage in device size and the need for exotic materials to perform certain tailored functions in an electronic device. Due to the mechanical nature of the CMP process, the planarization of thin and fragile layers has become a significant challenge, especially for semiconductor devices that contain low-k porous or air-gap containing structures. Further, in CMP applications that generate toxic byproducts or toxic waste, due the presence of toxic materials in the polished layer, such as indium gallium arsenide (InGaAs) materials, gallium arsenide (GaAs) materials, the handling of the substrates and contaminated system components becomes much more of a safety and/or cost of consumable parts issue.

Therefore, there is a need for a method and apparatus for planarizing a surface of a substrate that solves the problems described above. There is also a need for a planarization processes that can planarize the surface of the substrate without damaging the underlying layers, and also not expose maintenance personnel to toxic byproducts or toxic waste.

### SUMMARY OF THE INVENTION

The present disclosure generally includes apparatus and methods for planarizing a surface of a substrate using a plasma modification process. A process of plasma planarizing a surface of a substrate generally includes the removal and/or redistribution of a portion of an exposed surface of the substrate by use of an energetic particle beam while the substrate is disposed within a particle beam modification apparatus. In some embodiments, the planarization of a portion of an exposed surface of a substrate may be performed by use of a particle beam modification process that is performed in a sub-atmospheric pressure processing environment. The particle beam modification process may include the delivery of a charged particle beam that includes a spatially localized group of energetic particles (e.g., charged particles and/or neutrals) that are directed towards a surface of a substrate for a desired period of time. In some cases, the particle beam modification process may include the delivery of a charged particle beam that includes a spatially localized group of electrically charged particles that are directed towards a surface of a substrate.

Embodiments of the disclosure may provide an apparatus for planarization of a surface on a substrate, comprising a substrate support having a substrate supporting surface, a plasma generation source, and a beam extraction assembly. The plasma generation source assembly is configured to ionize a process gas. The beam extraction assembly may comprise a first electrode having a first aperture that is positioned to extract at least a portion of the charged particles formed in the plasma generation region, a second electrode having a second aperture that is positioned to receive a flow of the charged particles that passed through the first aperture. The extraction of the charged particles is done by electric fields generated by the electrodes positioned in the beam extraction assembly. The properties of the extracted charged particles depend on the geometry of the plasma boundary and relative biases applied to the components found in the beam extraction assembly. A first power source is generally configured to electrically bias the second electrode to increase the kinetic energy of the charged particles that have passed through the first aperture. The first and second apertures are positioned to direct the flow of the charged particles to the surface of the substrate during processing.

Embodiments of the disclosure may further provide an apparatus for modifying a surface of a substrate, comprising a substrate support having a substrate supporting surface, wherein a first direction is perpendicular to the substrate supporting surface, a first beam extraction assembly configured to simultaneously generate a first particle beam that exits the first beam extraction assembly in a second direction, wherein the first particle beam is directed towards the substrate supporting surface and the second direction is at a first grazing angle relative to the first direction and a second particle beam that exits the first beam extraction assembly in a third direction, wherein the second particle beam is directed towards the substrate supporting surface and the third direction is at the first grazing angle or a second grazing angle relative to the first direction, and an actuator that is configured to translate the substrate supporting surface relative to the first and the second particle beams.

Embodiments of the disclosure may further provide a method of planarizing a surface of a substrate in a processing region of a processing chamber, comprising delivering a first particle beam from a beam extraction assembly towards a substrate disposed on a substrate supporting surface of a substrate support, wherein the delivered first particle beam is provided in a first direction that is at a first grazing angle relative to a second direction which is perpendicular to the substrate supporting surface, delivering a second particle beam from the beam extraction assembly towards the substrate supporting surface, wherein the delivered second particle beam is provided in a third direction that is at the first grazing angle or a second grazing angle relative to the second direction, and moving the substrate relative to the first and second particle beams, or moving the first and second particle beams relative to the substrate, to reduce the non-planarity of a non-planar surface formed on the substrate.

Embodiments of the disclosure may further provide a system for planarizing a surface of a substrate, comprising a transfer chamber having a transfer region, a first process chamber that is coupled to the transfer chamber, a second process chamber that is coupled to the transfer chamber, wherein the second process chamber configured to deposit a layer on the substrate, and a substrate transfer robot disposed in the transfer region, and configured to load and unload substrates disposed in the first processing chamber and the second processing chamber. The first process chamber may comprise a substrate support having a substrate supporting surface, wherein a first direction is perpendicular to the supporting surface, a first beam extraction assembly configured to simultaneously generate a first particle beam that exits the first beam extraction assembly in a second direction, wherein the first particle beam is directed towards the substrate supporting surface and the second direction is at a first grazing angle relative to the first direction, and a second particle beam that exits the first beam extraction assembly in a third direction, wherein the second particle beam is directed towards the substrate supporting surface and the third direction is at the first grazing angle or a second grazing angle relative to the first direction, and an actuator that is configured to translate the substrate supporting surface of the substrate support relative to the first and the second particle beams.

Embodiments of the disclosure may further provide a method of modifying a surface of a substrate in a processing region of a processing chamber, comprising delivering a first particle beam from a beam extraction assembly towards a substrate disposed on a substrate supporting surface of a substrate support, wherein the delivered first particle beam is provided in a first direction that is at a first grazing angle relative to a second direction which is perpendicular to the substrate supporting surface, moving the substrate relative to the first particle beam, or moving the first particle beam relative to the substrate, to reduce the non-planarity of a non-planar surface formed on the substrate, and delivering a etching gas to the non-planar surface of the substrate while substrate is moved relative to the delivered first particle beam.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a cross-sectional view of a device structure formed on a surface of a substrate prior to performing a planarization process.

FIG. 1B is a cross-sectional view of the device structure after performing a conventional planarization process, wherein a feature within the device structure contains a feature that has a dishing type defect.

FIG. 2 is a schematic cross-sectional view of a device structure that is being processed using a particle beam modification process, according to an embodiment described herein.

FIG. 3 is a schematic side cross-sectional view of a particle beam modification apparatus, according to an embodiment described herein.

FIG. 4 is a schematic plan view of substrate that is receiving at least a portion of a particle beam generated from a particle beam modification apparatus, according to an embodiment described herein.

FIG. 5A is a schematic side view of a portion of a particle beam generating assembly, according to an embodiment described herein.

FIG. 5B is a schematic side view of a portion of a particle beam generating assembly, according to an embodiment described herein.

FIG. 6A is a schematic side view of a portion of a particle beam generating assembly, according to an embodiment described herein.

FIG. 6B is a schematic side view of a portion of a particle beam generating assembly, according to an embodiment described herein.

FIG. 6C is a schematic plan view of a shape of a formed particle beam, according to an embodiment described herein.

FIG. 6D is a schematic plan view of a shape of a formed particle beam, according to an embodiment described herein.

FIG. 7 is a plan view of a cluster tool including multiple-substrate processing chambers in accordance with one embodiment of the present invention.

FIG. 8 is a plan view of a cluster tool including multiple-substrate processing chambers, according to an embodiment described herein.

FIG. 9 is a plan view of a portion of a substrate processing chamber disposed on a cluster tool, according to an embodiment described herein.

FIG. 10 is a side view of a processing chamber that is configured to process a substrate, according to an embodiment described herein.

FIG. 11 is a side view of a linear type cluster tool including multiple-substrate processing chambers, according to an embodiment described herein.

FIG. 12 is a plan view of a linear type cluster tool including multiple-substrate processing chambers, according to an embodiment described herein.

FIG. 13 illustrates one or more method steps that can be used to perform a plasma modification process, according to an embodiment described herein.

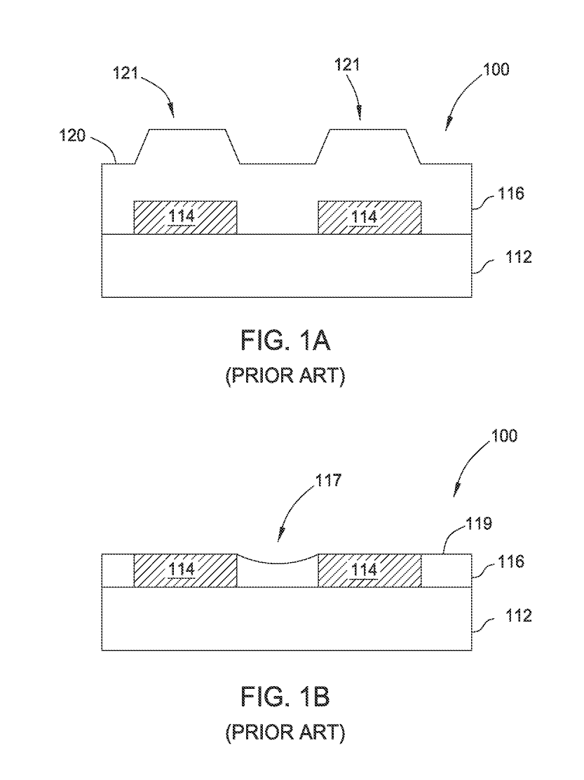

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure provided herein include apparatus and methods for modifying a surface of a substrate using a plasma modification process. The plasma modification process may include a plasma planarization process that generally includes the removal and/or redistribution of a portion of an exposed surface of the substrate by use of one or more energetic particle beams while the substrate is disposed within a particle beam generation apparatus. Embodiments of the disclosure may also provide a plasma modification process that includes one or more pre-planarization processing steps and/or one or more post-planarization processing steps that are all performed within one processing system. Some embodiments of the present disclosure may provide apparatus and methods for planarizing a surface of a substrate by performing all of the plasma modification processes within either the same processing chamber, the same processing system or within processing chambers found in two or more processing systems.

In some embodiments, the planarization of a portion of an exposed surface of a substrate may be performed by use of a particle beam modification process that is performed in a sub-atmospheric pressure processing environment. In general, a plasma modification process includes performing one or more steps that make an outer surface of a substrate relatively flat and/or smooth. In some embodiments, the modification process is used to remove an amount of deposited material overburden found on the surface of the substrate, while also planarizing the surface of the substrate. The particle beam modification process may include the delivery of one or more energetic particle beams that includes a spatially localized group of energetic particles that are directed towards and moved relative to a surface of a substrate for a desired period of time. The particles found in the formed one or more energetic particle beams may have approximately the same kinetic energy and are directed towards the surface of the substrate from a particle beam to help remove material and/or planarize the exposed surface of the substrate. In some cases, the particle beam modification process may include the delivery of a charged particle beam that includes a spatially localized group of electrically charged particles that are directed towards a surface of a substrate. The processed substrate may include one or more exposed regions that contain a conductive material, a semiconductive material and/or a dielectric material.

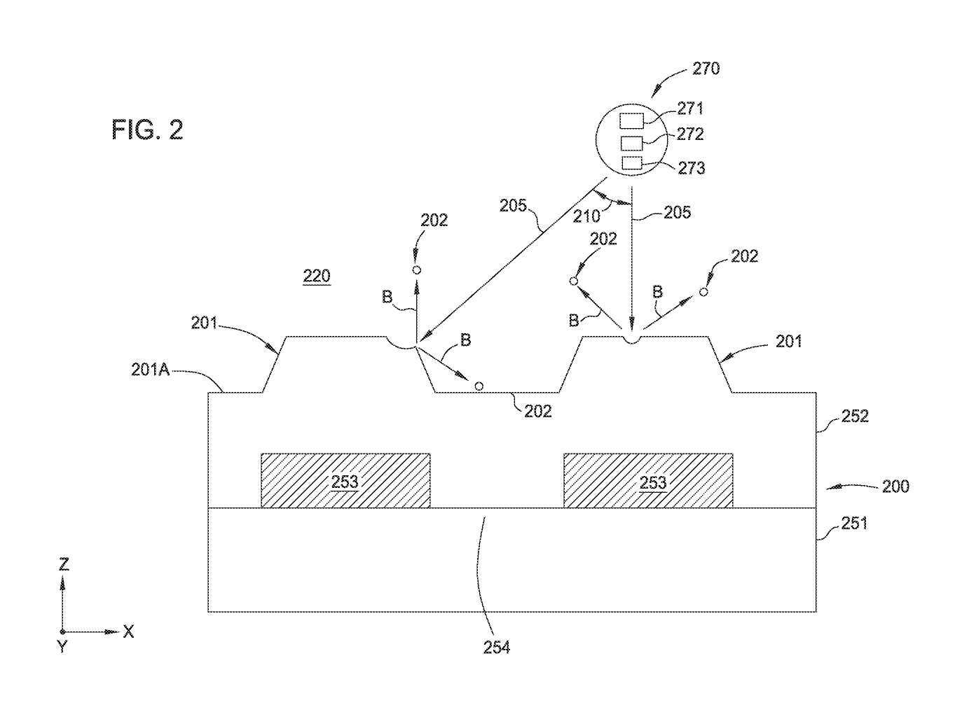

FIG. 2 illustrates a schematic cross-sectional view of a device structure 200 having a non-planar surface 201A that is being exposed to one or more energetic particle beams to planarize the non-planar surface 201A of the device structure 200. The device structure 200 may include a patterned layer 253, which is formed on a surface of the base substrate 251, and a deposited layer 252 that is formed over the patterned layer 253 and the base substrate 251. Due to the absence of material in various regions of the patterned layer 253, the upper surface of the deposited layer 252 will contain features 201, which form part of the non-planar surface 201A, which are to be removed by performing the particle beam modification process described herein.

The particle beam modification process generally includes the delivery of at least one energetic particle beam, hereafter particle beam 205, to the non-planar surface 201A of a device structure 200 from a beam extraction assembly 270 to remove material and/or planarize the exposed surface of the substrate. In general, as is discussed further below, the delivered particle beam(s) 205 are used to modify the surface of the substrate and may include charged particles and/or uncharged particles (e.g., neutrals and/or radicals). The particle beam modification process is generally performed in a moderate to low pressure environment within the processing region 220, such as at a processing pressure of between about 0.01 mTorr and about 1 Torr.

The particle beam modification process may include the delivery of one or more particle beams 205 to remove and/or redistribute portions of the non-planar surface 201A by use of a purely physical material planarization process, or in some cases by use of both a physical and a chemical material planarization process. The physical component of particle beam modification process generally includes the energetic bombardment of a portion of the surface of the substrate, whereby the energetic particles in the particle beam 205, which are generated by the beam extraction assembly 270, cause material on the surface of the substrate to be dislodged and/or ejected therefrom, as shown by arrows “B” in FIG. 2. The dislodged and/or ejected material, such as material 202, generated by the interaction of the surface of the substrate with the particle beam 205 will cause the material 202 to be redistributed on and/or removed from the surface of the substrate.

Typically, the higher the mass of the atoms and/or molecules that form the energetic particles in the particle beam 205, the greater the ability of the particle beam 205 to physically remove material from the surface of the substrate. The term “sputtering” is often used to describe the physical component of the particle beam modification process, and the term “sputter yield” is generally used herein to describe the ability of an energetic gas atom, or molecule, in the particle beam to remove atoms from the surface of the substrate. The higher the sputter yield, which is typically dependent on the mass and the kinetic energy of the particles (e.g., atom or molecule) in the beam, the more effective the energetic atoms are at removing material from the surface of the substrate. In some configurations, the particle beam comprises energetic ions and/or neutrals formed from a plasma that contains one or more gas atoms, such as argon (Ar), neon (Ne), krypton (Kr), xenon (Xe), radon (Rn), nitrogen (N), helium (He) and hydrogen (H), and/or molecules, such as nitrogen and hydrogen compounds (NₓH_{y}), or a combination of thereof (e.g., Ar/Xe). In some embodiments, the particle beam comprises energetic ions and/or neutrals formed from a plasma that contains molecules formed from gases containing elements such as germanium (Ge), silicon (Si), gallium (Ga), arsenic (As), Iodine (I), or a combination of gas atoms and molecules thereof (e.g., Ar/trimethylgallium (TMG)). In one example, the particle beam 205 comprises an argon ion beam.

Another, factor that can affect the ability of the particle beam 205 to remove and/or redistribute material on the surface of the substrate is the incident angle 210 of the directed particle beam, which is typically measured from a direction that is perpendicular, or normal, to the surface of the device structure 200. In FIG. 2, the particle beam 205₁ is oriented normal to the surface of the substrate and particle beam 205₂ is shown at an angle 210 to the surface of the device structure 200, which is also referred to herein as the grazing angle. In general, a particle beam 205 may be delivered in a direction that has an angle 210 from the normal that may vary from about zero degrees (e.g., normal) and less than about 90 degrees (e.g., ˜89.5 degrees). It is believed that particle beams 205 that have angles of 60 or greater, such as 70-80 degrees typically have good smoothing performance, which is the ability of the particle beam 205 to smooth the surface roughness found on the surface of the substrate. It is also believed that particle beams that have an angle 210 of 60-70 degrees or less will typically have a good sputter yield performance. However, in one example, in an effort to achieve good smoothing performance on a crystalline silicon (Si) substrate al keV energy beam is delivered at an incidence angle ranging from 30-60 degrees.

In general, the chemical material planarization component of the particle beam modification process will include a gas phase or vapor phase chemical interaction of the ions or radicals found in the particle beam 205, or gas phase, vapor phase and/or gas or vapor phase reactive species (e.g., radicals) supplied from the processing environment surrounding the particle beam 205, with the material at the surface of the substrate. Thus, the chemical interaction of chemical species found in the particle beam 205, or that interact with particle beam 205, is used to help remove and/or redistribute the material on the surface of the substrate by use of a non-physical method. In some cases, the chemical material planarization process may occur by reacting a gas or vapor phase etchant with the surface of the substrate. Therefore, in some embodiments, the particle beam 205 and/or environment surrounding the particle beam 205 comprise an etchant material, such as an etchant gas that contains a halogen gas, such as chlorine (Cl₂), fluorine (F₂), bromine (Br₂) and iodine (I₂), and/or molecules, such as ammonia (NH₃). In one example, the particle beam 205 comprises chlorine (CI) or fluorine (F) containing ions. In one example, the particle beam 205 comprises an inert gas and an etchant gas, such as a gas mixture that contains argon and fluorine or chlorine. In another example, the particle beam 205 comprises an inert gas and an etchant gas, where the etchant gas may contain fluorine (F₂), nitrogen trifluoride (NF), carbon tetrafluoride (CF₄), boron trifluoride (BF₃), xenon difluoride (XeF₂), boron trichloride (BCl₂), trifluoromethane (CHF₃), hexafluoroethane (C₂F₆), chlorine (Cl₂) or other fluorocarbons or chlorine containing gases. In another example, the particle beam 205 comprises an inert gas and the processing region surrounding the substrate includes an etchant gas, such as fluorine or chlorine.

The beam extraction assembly 270 typically includes a gas source 271, a plasma generation source 272 and an electrode assembly 273. The gas source 271 generally includes one or more sources of gas atoms, gas phase molecules or other vapor delivering sources that are able to provide a process gas that includes gas atoms, molecules, or vapor that when ionized by the plasma generation source 272 can be extracted by the electrode assembly 273 to form part of the particle beam 205.

The plasma generation source 272 generally includes a source of electromagnetic energy that is configured to deliver energy to a plasma generation region to form a plasma therein using the process gas delivered from the gas source 271. In general, the plasma generation source 272 can use one or more plasma generation techniques to form a plasma in the plasma generation region. The plasma generation techniques may include, for example, the delivery of electromagnetic energy to the plasma generation region from a capacitively coupled plasma source, an inductive coupled plasma source, a helicon type source, electron cyclotron resonance (ECR) type source and/or the delivery of microwave energy from a microwave source.

The electrode assembly 273 is generally a device that is used to extract ions generated within the plasma generation region of the plasma generation source 272 to form and deliver one or more energetic particle beams that each include a spatially localized group of energetic particles that are directed towards a surface of a substrate. The one or more energetic particle beams 205 may include a cylindrical shaped beam, a plurality of adjacent or overlapping cylindrical beams, or a ribbon shaped beam (e.g., a continuous rectangular shaped beam). The one or more energetic particle beams 205 can be moved relative to the non-planar surface 201A during processing and/or the substrate can be moved relative to the energetic particle beam 205 during processing to planarize the surface of the substrate. In some embodiments, as will be discussed further below, the electrode assembly 273 includes components that are adapted to adjust the trajectory (e.g., angle 210) of the generated energetic particle beams to the surface of the substrate to compensate for surface morphology variations on the non-planar surface 201A and/or improve the results of the particle beam modification process.

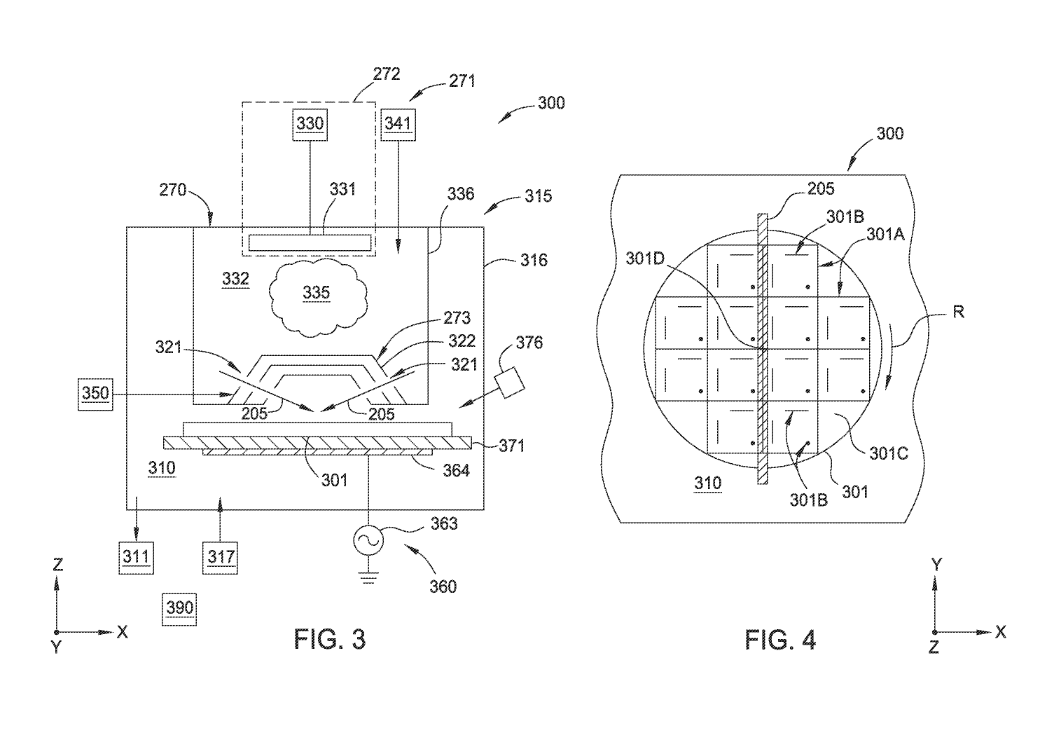

FIG. 3 is a schematic cross-sectional view of a processing chamber 300 that includes a beam extraction assembly 270 that is positioned to planarize a portion of a substrate 301 that is positioned to receive one or more of the energetic particle beams 205 that are generated and directed to the surface of the substrate by the beam extraction assembly 270. The processing chamber 300 generally includes a chamber assembly 315 and the beam extraction assembly 270. The chamber assembly 315 generally includes one or more walls 316 that enclose the processing region 310 in which the substrate 301 is disposed during the particle beam modification process. The chamber assembly 315 will also typically include a system controller 390, a pumping system 311 and a gas delivery source 317, which are used in combination to control the processing environment within the processing region 310. The pumping system 311 may include one or more mechanical pumps (e.g., rough pump, turbo pump) that are configured to control a desired pressure within the processing region 310. The gas delivery source 317 may include one or more sources that are configured to deliver an amount or a flow of an inert and/or a reactive gas (e.g., etchant gases) to the processing region 310. In some configurations, the chamber assembly 315 may also include a thermal source (not shown) (e.g., lamps, radiant heaters) that is controlled by the system controller 390 to adjust the temperature of the substrate 301 during processing. In one example, the system controller 390 is configured to control the gas composition, chamber pressure, substrate temperature, gas flow or other useful process parameter in the processing region 310 during the particle beam modification process.

The chamber assembly 315 will also typically include a substrate support assembly 371 that is adapted to support the substrate during processing. In some cases, the substrate support assembly 371 may also include one or more actuators (not shown) that are adapted to translate or rotate the substrate relative to the electrode assembly 273 during processing. In applications that require the substrate 301 to be translated or rotated, some of the driving components, such as an actuator or a motor are positioned outside of the processing region 310 and are coupled to the elements that support the substrate 301 within the processing region 310 using a conventional vacuum feed-through or other similar mechanical device. In some configurations, one or more of the actuators are adapted to position the substrate 301 relative to the electrode assembly 273 so that a desired gap 372, which is measured in the Z-direction in FIG. 3, is formed between the substrate 301 and the electrode assembly 273.

As noted above, the beam extraction assembly 270 typically includes a gas source 271, a plasma generation source 272 and electrode assembly 273. In one configuration, as illustrated in FIG. 3, the gas source 271 generally includes one or more separate gas sources 341 that are each configured to deliver a process gas (e.g., gas atoms, gas phase molecules or other vapor containing materials) to the plasma generation region 332 of the beam extraction assembly 270. The gas source 341 is configured to deliver a process gas that may include an inert gas and/or an etchant gas that are used to form at least part of the particle beam 205, as discussed above and further below.

Referring to FIG. 3, the pumping system 311 may also be separately connected to the processing region 310 and the plasma generation region 332 so that different pressures can be maintained in each region. In one example, the pumping system 311, gas delivery source 317 and/or gas sources 341 are configured to work together to maintain the plasma generation region 332 at a pressure greater than the processing region 310 during processing. In one configuration, the plasma generation region 332 includes a pump (not shown) that is separate from the pumping system 311, and is configured to maintain the pressure in the plasma generation region 332 at a desired level.

As noted above, the plasma generation source 272 generally includes a source of electromagnetic energy that is configured to form a plasma 335 in the plasma generation region 332 using the process gas delivered from the one or more gas sources 341. The plasma generation source 272 may include a power source 330 and an antenna 331, which is in electrical communication with the plasma generation region 332. In one non-limiting example, the antenna 331 may be a capacitively coupled electrode that is adapted to generate the plasma 335 in the plasma generation region 332, when radio frequency (RF) energy is delivered from the power source 330 to the antenna 331 during processing.

The electrode assembly 273 may include a beam controller 350 and beam delivery element 322 that are used to extract charged particles formed within the plasma generation region 332 to form and deliver one or more particle beams 205 to a surface of a substrate 301 through one or more apertures 321 that are formed in the beam delivery element 322. The shape of the aperture 321 is formed so that a beam having a desired shape is created by the beam delivery element 322, such as a ribbon shaped or cylindrical shaped beam. In some configurations, the aperture 321 is also positioned and aligned to direct the particle beam 205 to a desired portion or region of the surface of the substrate during processing. The system controller 390 is generally configured to control the generation and delivery of the one or more energetic particle beams 205 by sending commands to the various components found in the beam controller 350 and beam delivery element 322.

The chamber assembly 315 may also include a bias assembly 360 that is in communication with the system controller 390 and is configured to deliver energy to the processing region 310 of the processing chamber 300. The bias assembly 360 generally includes a support electrode 364 and a source 363, which is coupled to ground and can be used to remove any accumulated charge found on the substrate 301 during or after performing the plasma modification process. To remove any residual charge found on the substrate, the source 363 may utilize an AC or high frequency power source (e.g., 2 MHz-200 MHz power source) that is configured to form a plasma over the substrate 301 during one or more phases of the plasma modification process performed in the processing region 310. It is believed that the formed plasma will provide a path to ground that will allow any stored charge in the substrate to be dissipated. In some cases the bias assembly 360 can also be used to help control the trajectory and/or energy of the particle beam 205 that strikes the surface of the substrate 301 during the plasma modification process.

FIG. 4 is a plan view of the substrate 301 that is disposed within the processing region 310 of the processing chamber 300. As illustrated in FIG. 4, the substrate 301, may include a plurality of die 301A that contain a plurality of features 301B formed therein. The features 301B will generally include protrusions and depressions in the non-planar surface 301C of the substrate 301, which are to be planarized during the particle beam modification process. The features 301B may be similar to the features 201 discussed above in conjunction with FIG. 2.

In one configuration, as illustrated in FIG. 4, a single ribbon shaped particle beam 205 is delivered across the surface of the substrate 301 to planarize the non-planar surface 301C of the substrate 301. In some embodiments, the substrate 301 is rotated “R” relative to the particle beam 205 about a substrate center 301D to assure that the directional nature of plurality of features 301B on the substrate 301 do not hinder the ability of the particle beam 205 to evenly planarize the non-planar surface 301C. In this configuration the processing chamber 300 may include a rotating substrate support assembly 371 (FIG. 3) that is configured to position, support and rotate the substrate 301 relative to the particle beam 205 when the substrate 301 is disposed within the processing region 310. By varying the angular orientation of the surface of the substrate 301 relative to the particle beam 205, any shadowing effects created by the differing orientation of the features 301B relative to the incident particle beam 205 can be reduced or minimized, which will improve the ability of the beam extraction assembly 270 to uniformly planarize the non-planar surface 301C of the substrate 301.

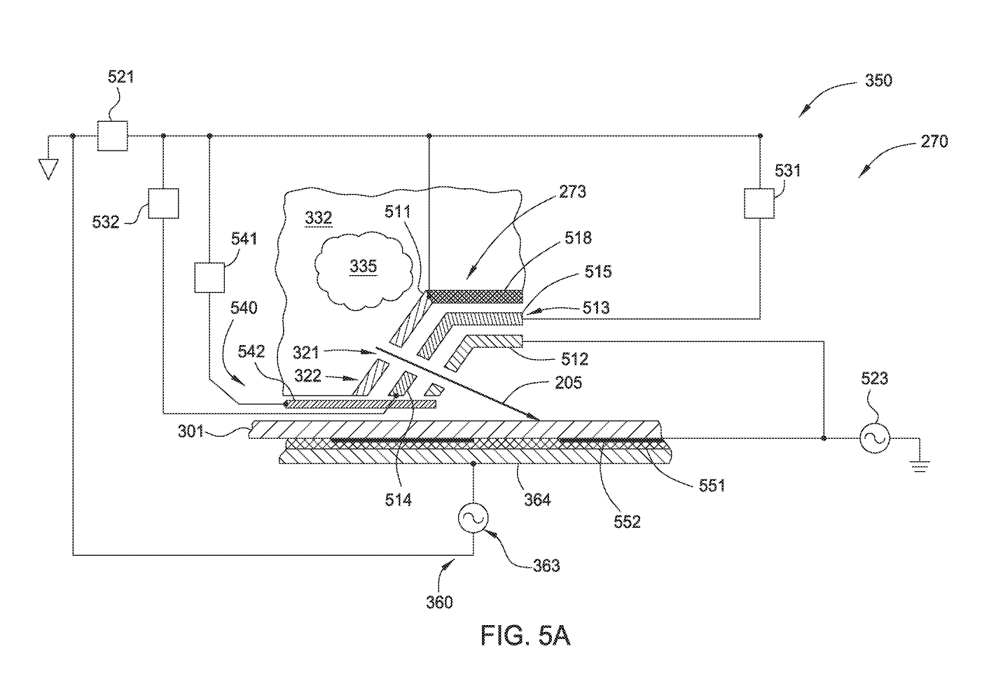

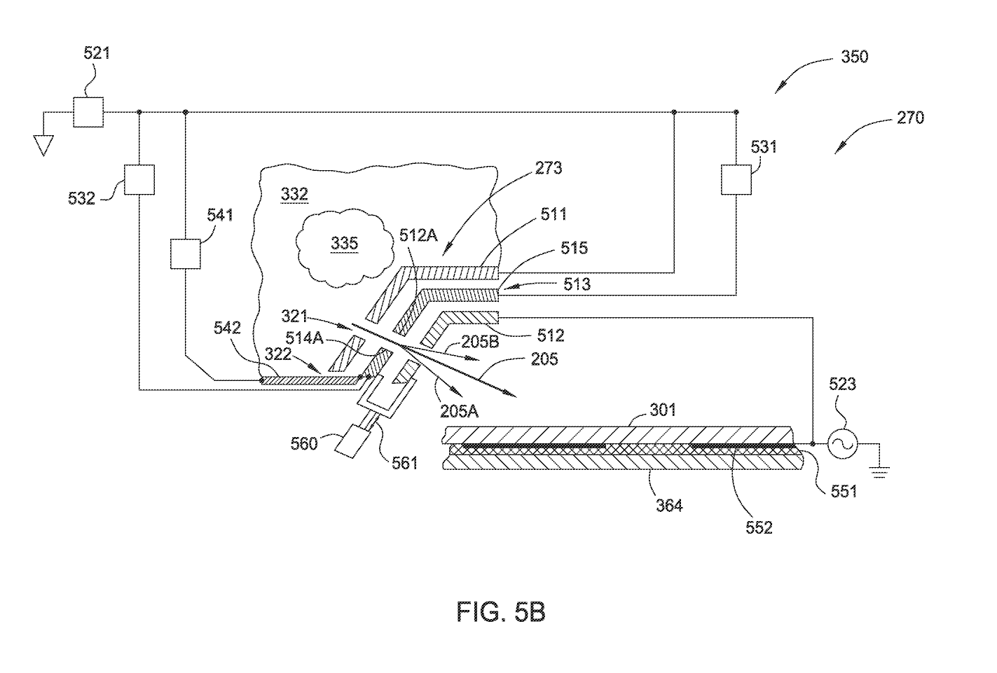

FIG. 5A is a schematic cross-sectional view of a portion of the beam delivery element 322 that is coupled to the beam controller 350 that is found within the beam extraction assembly 270. In one configuration, as illustrated in FIG. 5A, the beam controller 350 includes “multi-element extraction assembly,” such as a “triode” assembly, that is configured to extract charged particles (e.g., ions) generated in the plasma generation region 332 and form and deliver a particle beam 205 in a desired direction to desired region of a surface of a substrate 301 through one or more apertures 321 formed in the beam delivery element 322. Extraction of the charged particles is done by electric fields generated by the electrodes positioned in the beam extraction components of the beam delivery element 322. Extraction conditions depend on the geometry of the plasma boundary and relative biases applied to the beam extraction components found in the beam delivery element 322. In one configuration, the beam delivery element 322 will generally include a plasma aperture electrode 511, a local ground electrode 512 and steering electrodes 513 that are all connected to various biasing components found in the beam controller 350. The biasing components found in the beam controller 350, such as power sources 521, 531, 532 and 541 may include power supplies that are each be able to drive the various connected electrodes at a positive or a negative direct current (DC), alternating current (AC) and/or radio frequency (RF) provided potential. The plasma aperture electrode 511 may include an inactive region 518 that generally does not participate in the formation of the particle beam 205. The steering electrodes 513, also sometimes referred to herein as a suppression electrode(s), may include a first steering electrode 514 and/or a second steering electrode 515 that are connected to various biasing components found in the beam controller 350. Each of the electrodes 511-515 may include two or more conductive pieces of material that are electrically coupled to each other to share a same voltage potential. Alternatively, each set of electrodes 511-515 may be a one-piece structure that each have an aperture for forming or generating the particle beam 205. Therefore, in this case, each set of electrodes can be thought of as a single electrode having a single voltage potential. The apertures 321 formed in the various electrodes found in the beam delivery element 322 may have a circular shape, an oval shape, a slot shape (e.g., slit has an aspect ratio that is different in at least two directions) or any other desirable shape.

In operation, the plasma aperture electrode 511, the steering electrodes 513, and the local ground electrode 512 can be independently biased, such that the properties of the particle beam 205, such as particle beam energy (e.g., kinetic energy) and direction, can be controlled. Initially, an optional power source 521 is configured to provide a reference bias on the plasma aperture electrode 511, so that ions found in the plasma 335 can be accelerated towards plasma aperture electrode 511 and/or the steering electrodes 513. Since it may be possible to form positive and negative ions in the plasma 335 the biases applied to the various electrodes may be adjusted accordingly to generate and deliver a particle beam 205 having a desired composition and energy to the surface of the substrate 301.

In some configurations, the plasma aperture electrode 511 is maintained at a negative potential (e.g., DC, AC or RF potential) by the optional power source 521 and thus the plasma potential formed by the plasma generation source 272 is adjusted relative to the plasma aperture electrode 511, so that a ready supply of ions can be generated and sustained in the plasma 335 and allow a portion of the formed ions to be extracted by the relative bias formed between the plasma aperture electrode 511 and the plasma 335. The ions formed in the plasma 335 may enter the aperture 321 formed in the plasma aperture electrode 511 at an initial energy of, for example, about 10 eV to about 5 keV. The energy of the ions entering the aperture 321 formed in the plasma aperture electrode 511 may be adjusted by altering the bias applied to the plasma aperture electrode 511 by the power source 521.

The ions entering the aperture 321, which now form part of the forming particle beam 205, are accelerated (e.g., increased kinetic energy) due to the forward bias applied between the plasma aperture electrode 511 and the steering electrodes 513 by either or both of the power sources 531 and 532. In general, a “forward bias” will include the application of a bias that causes the ions in the particle beam to be accelerated as they pass from the plasma aperture electrode 511 to the local ground electrode 512. In one example, for cases where the ions generated in the plasma 335 have a positive charge the relative bias applied between the plasma aperture electrode 511 and at least one of the steering electrodes 513 may be on the order of a negative 5 to 15 keV, such as about 10 keV.

The energy of the charged particles passing through the slit formed in, or between, the steering electrodes 513 is then affected by the relative bias created between the steering electrodes 513 and the local ground electrode 512. Typically, the relative bias formed between the steering electrodes 513 and the local ground electrode 512 will be a decelerating field. Also, in general, it is desirable for the local ground electrode 512 and the substrate 301 to be maintained at the same potential. In one example, the local ground electrode 512 and the substrate 301 are maintained a ground potential. Typically, one or more conductive elements 552 formed in the substrate support assembly 371 are used to control the relative bias generated between the substrate 301 and the local ground electrode 512. The plurality of conductive elements 552, which may be disposed in a dielectric material 551 within the substrate support assembly 371, may be in electric communication with a surface of the substrate 301. In one example, the conductive elements 552 may include metallic elements formed on a substrate supporting surface of the substrate support assembly 371, or are formed by use of separate conductive lift pins or other chamber elements found within the processing chamber 300.

Referring back to FIG. 5A, in some configurations, it is desirable to adjust the potential applied to the local ground electrode 512 and the steering electrodes 513 by the power source 523 (e.g., DC or RF potential) such that the potential versus earth ground is at a desirable level. In some cases, the relative bias formed between the steering electrodes 513 and the local ground electrode 512 is used to decelerate (e.g., reduced kinetic energy) the charged particles found in the forming particle beam 205. In the case where a decelerating field is desired, and the charged particles in the forming particle beam 205 are positively charged, the relative bias formed between the steering electrodes 513 and the local ground electrode 512 is positive, or in other words is less negative than the bias created between the plasma aperture electrode 511 and the steering electrodes 513.

Upon reaching the slit, or aperture, formed in the local ground electrode 512, the particle beam 205 may have an energy of, for example, approximately 0.1 keV and about 20 keV. In another example, the particle beam 205 energy may be between about 5 keV and about 10 keV. The particles exiting the slit, or aperture, formed in the local ground electrode 512 will then flow to and strike the exposed surface of the substrate so as to cause a modification to the surface of the substrate (e.g., planarize the surface of the substrate). In one case, the particles in the formed particle beam 205 “drift” at the kinetic energy achieved at the exit of the slit formed in the local ground electrode 512 to the surface of the substrate. In another case, the source 363 in the bias assembly 360 is used to alter the energy of the ions in the particle beam 205 by applying a bias to the support electrode 364 (e.g., apply a DC or RF bias potential).

In some embodiments, the electrode assembly 273 may also include an electric field control assembly 540 that is adapted to actively or passively control the shape of the field lines generated by the beam delivery element 322. Control of the shape of the field lines generated by the components within the beam delivery element 322 can be useful to effectively control the trajectory of the charged particles formed in the particle beam 205. In one configuration, the electric field control assembly 540 includes a control element 542 that may include a layer of a dielectric material, semiconductor material or conductive material that is positioned between the components found within the beam delivery element 322 and the substrate 301 to alter the shape of the electric field lines that extend through the processing region 310 of the process chamber 300. The control element 542 may be positioned adjacent to or near the various components found within the beam delivery element 322.

In one configuration, the electric field control assembly 540 includes a control element 542 that is electrically coupled to one or more of the steering electrodes 513 (FIG. 5B) so that the control element 542 is maintained at the same potential as the one or more of the steering electrodes 514, 515. In one example, the control element 542 may include a conductive mesh or grid that is used to inhibit formation of or alter the shape of the electric field lines that extend through the processing region 310.

In another configuration, the electric field control assembly 540 includes a control element 542 that is separately biased by a power source 541 to actively control the shape of the electric field lines that extend through the processing region 310 by use of commands sent from the system controller 390. In this configuration, the control element 542 is separately biased to a potential that may be different than the potential applied to the steering electrode(s) 514, 515 to alter the shape of the electric field lines that extend through the processing region 310. In case where the extracted ions have a positive charge the bias applied to the control element 542 will have a negative potential, and where the extracted ions have a negative charge the bias applied to the control element 542 may have a positive potential.

In some embodiments, a bias can be applied to one or more of the steering electrodes 513 to alter the trajectory of the particle beam 205 in a desired direction. FIG. 5B is a schematic cross-sectional view of a portion of the beam delivery element 322 that is found within the beam extraction assembly 270, according to an embodiment described herein. In one configuration, by applying a bias to either the first steering electrode 514 or the second steering electrode 515 the trajectory of the particle beam 205, and thus its exiting direction, can be altered. In one example, by applying a larger forward bias to the first steering electrode 514 by the power source 532 versus the bias applied to the second steering electrode 515 by the power source 531, the particle beam will tend to deflect towards the surface 514A of the first steering electrode 514 to form the particle beam 205A. Alternately, by applying a larger forward bias to the second steering electrode 515 by the power source 531 versus the bias applied to the first steering electrode 514 by the power source 532 the beam will tend to deflect towards the surface 515A of the second steering electrode 515 to form the particle beam 205B.

In one configuration of the electrode assembly 273, as illustrated in FIG. 5B, the position of the first steering electrode 514 and/or the second steering electrode 515 relative to the particle beam 205 may be adjusted by use of an actuator 560 (e.g., linear servo motor). In some cases, the actuator 560 is able to move either or both of the steering electrodes 514, 515 and the local ground electrode 512 relative to the center of the aperture 321 formed in the beam delivery element 322 to adjust the trajectory of the particle beam 205 exiting the electrode assembly 273. Therefore, in some cases by applying a desirable bias to either of the steering electrodes 514, 515 and/or adjusting the position of either of the steering electrodes 514, 515 and local ground electrode 512 relative to the center of the aperture 321 the trajectory, or direction, of the particle beam 205 can be adjusted as desired.

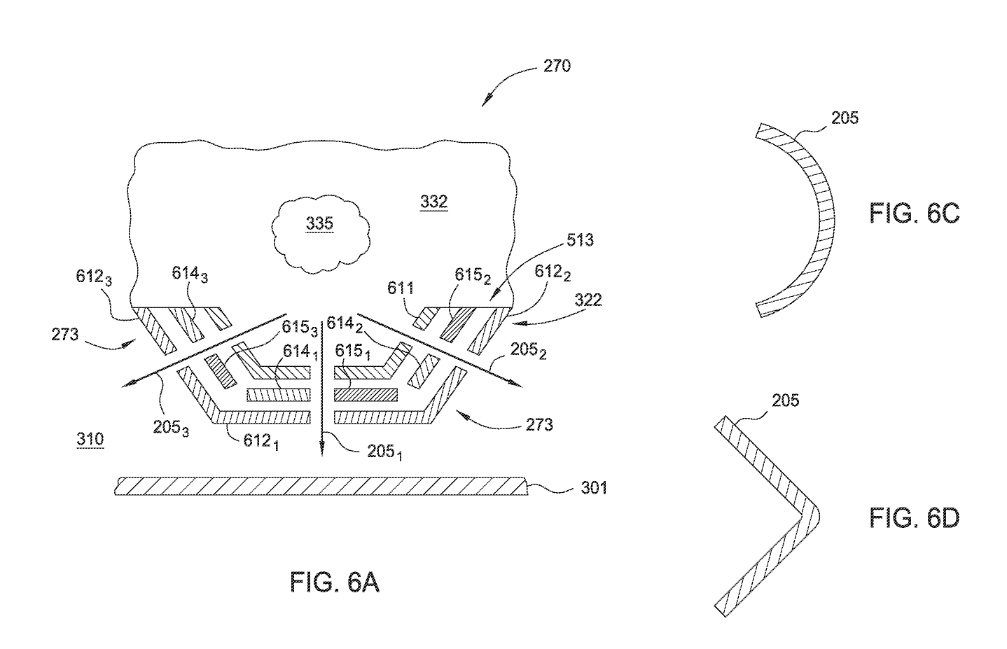

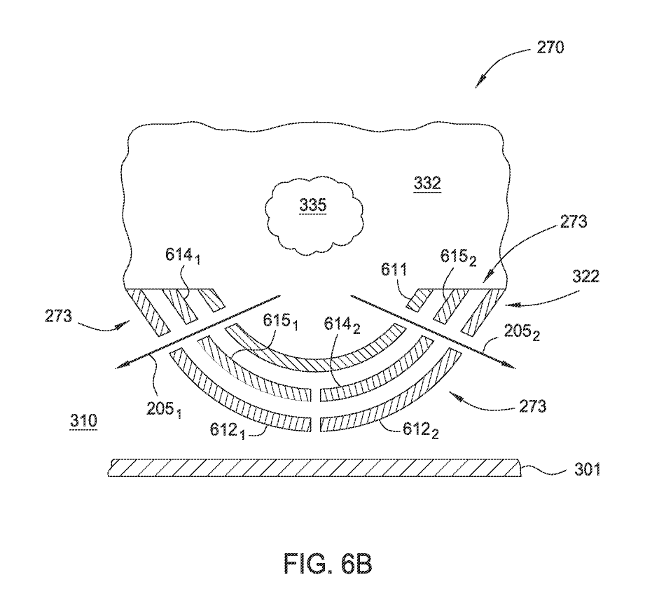

FIG. 6A, is a schematic side view of an alternate configuration of a particle beam generating assembly, according to an embodiment described herein. The beam delivery element 322 in this case is formed in convex shape, and is similarly coupled to the beam controller 350 (not shown) that is found within the beam extraction assembly 270. As shown, the extraction assembly 270 includes a “triode” assembly that is configured to extract charged particles generated in the plasma generation region 332, and form and deliver one or more particle beams, such as particle beams 205₁, 205₂ and 205₃, to a surface of a substrate 301 through one or more apertures 321 formed in the beam delivery element 322. In this configuration, the beam delivery element 322 will generally includes at least a plasma aperture electrode 611, a local ground electrode 612 and steering electrodes 613 that are connected to various biasing components found in the beam controller 350, as similarly discussed above. The steering electrodes 613 may include steering electrodes 614₁-614₃ and 615₁-615₃ that are each connected to separate biasing components (not shown) found in the beam controller 350 to separately control the trajectory and energy provided to each of the generated particle beams 205₁, 205₂ and 205₃. In some configurations, the plasma aperture electrode 611 and/or the local ground electrode 612 may also be segmented, such that a different bias can be applied to each of the beams 205₁-205₃ to control the amount of energy ultimately delivered to the substrate by each particle beam. In one example, the beam delivery element 322 includes a particle beam 205₁ that is oriented at a normal angle to the surface of the substrate and at least one other particle beam 205₂ or particle beam 205₃ that is at angle to the surface other than normal to the surface. The beam 205₁ that is directed at a normal or near normal angle will typically have a high sputter yield (or material removal efficiency), while the other particle beam 205₂ or particle beam 205₃ will tend to have a better smoothing efficiency. The planarization process performed by use of the two particle beams that are delivered at two different angles can provide a plasma modification process that is able to rapidly plasma planarize a surface of a substrate, and also shape the substrate surface so that it has a desirable flatness and surface smoothness.

FIG. 6B, is a schematic side view of another configuration of a particle beam generating assembly, according to an embodiment described herein. The beam delivery element 322 in this case is formed in a spherical shape, and is similarly coupled to the beam controller 350 (not shown) that is found within the beam extraction assembly 270. While not intending to limit to the illustrated spherical shaped beam delivery element 322 configuration, in one example, the beam extraction assembly 270 is configured to form and deliver two particle beams 205₁ and 205₂ that are each delivered at an angle to a surface of a substrate 301. In this configuration, the beam delivery element 322 will generally includes at least a plasma aperture electrode 611, a local ground electrode 612 and steering electrodes 613 that are connected to various biasing components found in the beam controller 350, as similarly discussed above. The steering electrodes 613 may include steering electrodes 614₁-614₂ and 615₁-615₂ that are connected to separate biasing components found in the beam controller 350 to separately control the trajectory and energy provided to each of the generated particle beams 205₁ and 205₂. In some configurations, the second electrode may be segmented (e.g., local ground electrodes 612₁ and 612₂), such that a different bias can be applied to each of the particle beams 205₁-205₂ to control the amount of energy ultimately delivered to the substrate by each beam.

FIGS. 6C and 6D are schematic plan views of some examples of shapes of particle beams 205 that may be formed by one or more of the beam extraction assemblies described herein. While most of the schematic representations of the particle beam 205 provided herein have a linear shape, such as the particle beams 205 shown in FIGS. 4, 8, 9 and 12, this configuration is not intended to be limiting as to the scope of the invention provided herein. As illustrated in FIG. 6C, in some cases, the particle beam 205 has a non-linear shape, such as a curved or arcuate shape when it strikes the surface of the substrate. In another example, as illustrated in FIG. 6D, the particle beam 205 is shaped to from a multiple segmented curve when it strikes the surface of the substrate. The shape of the particle beam 205 that strikes the surface of the substrate may also be controlled by adjusting the formed shape of the slit(s) 321 found in the beam delivery element 322 and/or by use of multi-segmented steering electrodes 514, 515 (FIGS. 5A-5B) that are disposed adjacent to an aperture (e.g., used to alter the trajectory of various parts of a single ribbon beam) formed in the beam extraction assembly 270.

In some configurations of the processing chamber 300, an plasma modification process endpoint detection technique is used to determine when the planarization process is complete. In one configuration, the endpoint detection technique includes an optical endpoint monitoring system 376 that is able to detect when a layer on the surface of the substrate has been removed or when a property of the material found within the processing region 310 has changed due to the completion of the plasma modification process. In one example, the property of the material within processing region may change as the gas phase concentration in the processing region changes after an upper most layer has been substantially removed from the substrate and a next underlying layer on the substrate is exposed to the particle beam 205. In general, an optical monitoring system that is able to detect an endpoint may include a light source (not shown), a light detector (not shown), and sensing circuitry (not shown) that is used to send and receive signals between a remote controller (e.g., system controller 390) and the light source and a light detector. In one aspect, a method of detecting an endpoint includes performing the plasma modification process on a first layer formed on a substrate, and during processing, obtaining a sequence over time of measured optical spectra with the optical monitoring system. The measured optical spectrum can then be compared with previously stored spectrum and/or other stored parameters that are used to determine the endpoint, which can then be used to decide when to stop the plasma modification process. In another configuration, optical monitoring system is able to detect an endpoint by use of reflectometry process, where the optical monitoring system includes a light source (not shown), a light detector (not shown), and sensing circuitry (not shown) that are used to send and receive signals that are reflected off of the processed surface of the substrate. The measured optical signals used in the reflectometry end point sensing process can then be compared with previously stored data and/or other stored parameters so that the system controller can determine when to stop the plasma modification process.

### Cluster Tool Configuration Examples

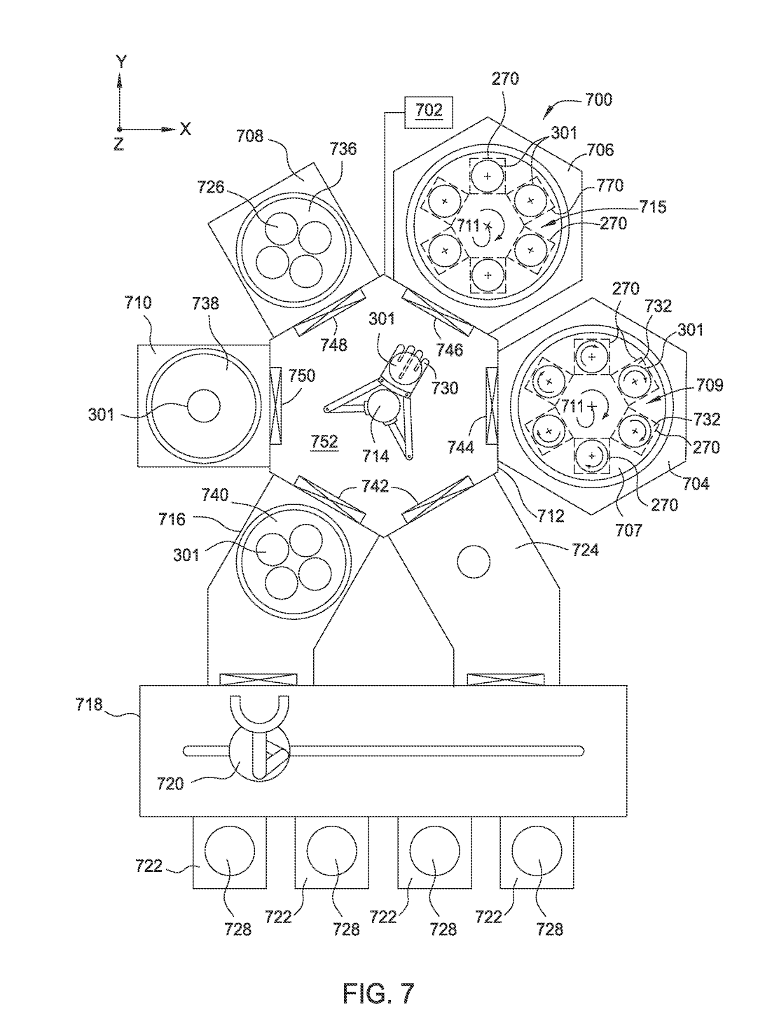

FIG. 7 is a plan view of a processing system 700 that may be used to perform one or more substrate processing steps in accordance with one embodiment of the present invention. One or more of the processing chambers found in the processing system 700 are adapted to perform the plasma modification process that is described herein. The processing system 700 generally creates a processing environment where various processes can be performed on a substrate, such as the particle beam modification process. The processing system 700 generally include a system controller 702 programmed to carry out various processes performed in the processing system 700.

The system controller 702 may be used to control one or more components found in the processing system. In some configurations, the system controller 702 may form part of the system controller 390, which is discussed above. The system controller 702 is generally designed to facilitate the control and automation of the processing system 700 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and control support hardware (e.g., sensors, robots, motors, lamps, etc.), and monitor the processes performed in the system (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 702 determines which tasks are performable on a substrate in one or more of the process chambers and in the processing system 700. Preferably, the program is software readable by the system controller 702 that includes code to perform tasks relating to monitoring, execution and control of the movement, support, and/or positioning of a substrate along with the various process recipe tasks and various chamber process recipe steps being performed in the processing system 700.

The processing system 700 includes a plurality of processing chambers 704, 706, 708, 710 that are coupled to a transfer chamber 712. Each processing chamber 704, 706, 708, 710 may be configured to process one or more substrates 301 at a time. The processing chamber 704, 706, 708, 710 may have the same or different substrate processing capacities. For example, the processing chamber 704 and 706 can simultaneously process six substrates, while processing chambers 708 and 710 may be adapted to process one or more substrates at a time.

The processing system 700 may also include load lock chambers 716 and 724 that are connected to the transfer chamber 712. In one embodiment, the load lock chambers 716 and 724 may also be used as one or more service chambers for providing various functions for processing within the processing system 700, for example, substrate orientation, substrate inspection, heating, cooling, degassing, or the like. The transfer chamber 712 defines a transfer volume 752. A substrate transfer robot 714 is disposed in the transfer volume 752 for transferring substrates 301 among the processing chambers 704, 706, 708, 710, the load lock chambers 716 or 724. The transfer volume 752 is in selective fluid communication with the processing chambers 704, 706, 708, 710, the load lock chambers 716 and 724 via slit valves 744, 746, 748, 750, 742 respectively. In one example, the transfer volume 752 may be maintained at a sub-atmospheric pressure while the substrates are transferred through the processing system 700.

The processing system 700 includes a factory interface 718 connecting one or more pod loaders 722 and the load lock chambers 716 and 724. The load lock chambers 716 and 724 provides a first vacuum interface between the factory interface 718 and the transfer chamber 712, which may be maintained in a vacuum state during processing. Each pod loader 722 is configured to accommodate a cassette 728 for holding and transferring a plurality of substrates. The factory interface 718 includes a Fl robot 720 configured to shuttle substrates between the load lock chambers 716 and 724, and the one or more pod loaders 722.

The substrate transfer robot 714 includes a robot blade 730 for carrying one or more substrates 301 among the processing chambers 704, 706, 708, 710, the load lock chamber 716 and 724, and loading/unloading each chamber.

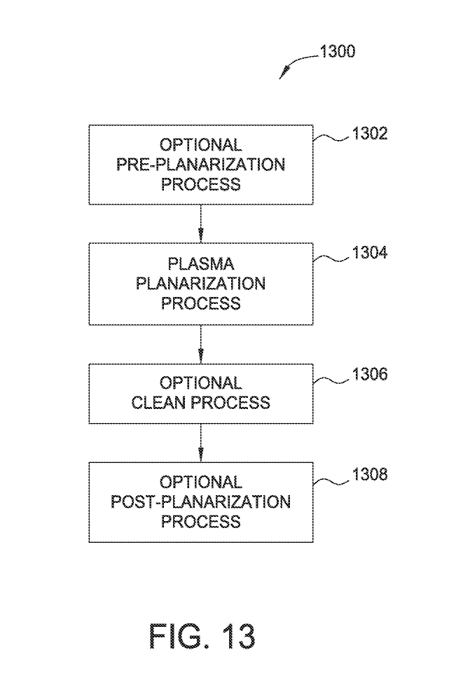

Each processing chamber 704, 706, 708, 710 may be configured to perform the plasma modification process described herein. However, in one embodiment of the processing system 700, the process chambers 704 and 706 are adapted to perform the plasma modification process on a plurality of substrates using a plurality of beam extraction assembly 270. In one configuration process chambers 708 and 710 may each be adapted to perform one or more preprocessing steps on the substrates 301 before they are inserted into either processing chamber 704 or 706, or post-processing steps on the substrates 301 after they have been processed in either processing chamber 704 or 706. Examples, of the preprocessing or post-processing steps are further described below in conjunction with FIG. 13.

In one configuration of the processing system 700, the processing chambers 704 and 706 each include a substrate conveyance assembly 707 that is configured to retain and transport a plurality of substrates 301 that are retained within the processing regions 709 or 715 of the processing chambers 704 or 706, respectively. In one example, each of the substrate conveyance assemblies 707 are adapted to retain six substrates 301 and rotate the substrates 301 about a central axis 711 of the processing chamber 704 or 706 by use of conventional rotational hardware components. The substrate conveyance assembly 707 is thus able to transfer and position the substrates 301 relative to each of the beam extraction assemblies 270 that are positioned to process substrates 301 found in the processing region 709 or 715 of the processing chamber 704 or 706, respectively.

In some configurations, as illustrated in processing chamber 704 in FIG. 7, each of the substrates 301 that are disposed on the substrate conveyance assembly 707 can be rotated relative to the beam extraction assembly 270 by use of a substrate rotation assembly 732. The substrate rotation assembly 732 generally includes an actuator (not shown) that is configured to rotate a substrate supporting element (not shown) relative to the substrate conveyance assembly 707.

However, in some embodiments, the particle beam 205 generated by each beam extraction assembly 270 may be rotated or translated relative to the surface of the substrate (e.g., X-Y plane). In this case, an actuator (not shown) that is found within each beam extraction assembly 270 is configured to rotate or translate the beam delivery element 322 (FIG. 3) relative to the substrate to minimize any shadowing effects created by the orientation of features formed on the surface of the substrate.

During a process sequence performed in processing chamber 704, for example, the transfer robot 714 delivers a substrate 301 to an open position on the substrate conveyance assembly 707 and then the substrate conveyance assembly 707 and system controller 702 work together to position the substrate 301 under one of the beam extraction assemblies 270 for processing. The transfer robot 714 may repeat this task of sequentially loading substrates until the all of the positions in the processing chamber 704 have been filled, and then a batch processing plasma modification processing sequence is performed on all of the substrates 301 at one time. After the substrate(s) have been sufficiently processed within the processing chamber 704 the transfer robot 714 is configured to remove the substrate from the processing region 709.

Alternately, in some cases, the transfer robot 714 may insert and remove substrates from the processing chamber 704 as needed, so that a sequentially performed plasma modification process can be performed on each substrate 301 that is serially loaded into the processing chamber 704. In some processing configurations, the substrate conveyance assembly 707 is configured to sequentially position the received substrates under each of the beam extraction assemblies 270 so that at least a portion of the plasma modification processing sequence is performed on the substrate by each of the beam extraction assemblies 270 before the substrate exits the process chamber. In one configuration, each of the beam extraction assemblies 270 within the processing chamber 704 are configured to separately provide the same type of particle beam 205 to the surface of the substrate during the sequential process. In another configuration, two or more of the beam extraction assemblies 270 are each adapted to separately provide a particle beam 205 that has some different processing characteristic, such as beam energy, beam direction, beam composition (e.g., gas ions), or other useful property to the surface of the substrate. In general, the direction of the generated particle beam 205 exiting the beam extraction assemblies 270 can be defined in 3D space, and thus, in one example, can be at least partially defined by the beam angle (e.g., angle 210) and the beam angle relative to the radial position of the substrate conveyance assembly 707.

In some configurations of the processing chambers 704 or 706, the area or region below each of the beam extraction assemblies 270 may be isolated from adjacent beam extraction assemblies 270, so that different processing environments can be maintained below each beam extraction assembly 270. In one configuration, an at least partially enclosed region (e.g., gas curtain or physical walls) is formed around each beam extraction assembly 270, such that each of the substrates 301 can be positioned within the sub-processing region by the substrate conveyance assembly 707 and be separately processed by the beam extraction assembly 270.

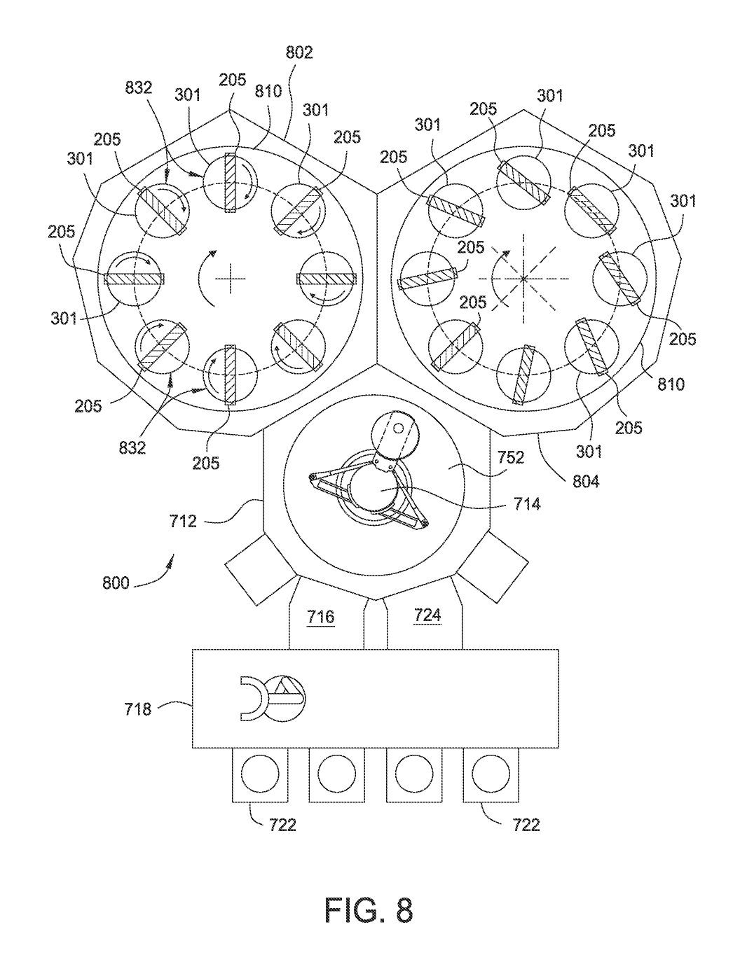

FIG. 8 is a plan view of a processing system 800 that may be used to perform one or more substrate processing steps in accordance with one embodiment of the present invention. The two processing chambers 802 and 804 found in the processing system 800 are adapted to perform at least part of the plasma modification process that is described herein. The processing chambers 802 and 804 are coupled to a transfer chamber 712, which is described above. In this example, each processing chamber 802 and 804 is configured to process eight substrates 301 at a time. As similarly discussed above, the processing system 800 also includes a load lock chambers 716 and 724 that are connected to the transfer chamber 712. A substrate transfer robot 714 is disposed in the transfer volume 752 for transferring substrates 301 among the processing chambers 802 and 804 and the load lock chambers 716 or 724.

The processing chambers 802 and 804 may each include a substrate conveyance assembly 810 that is configured to retain and transport a plurality of substrates 301 that are retained within the processing regions of the processing chamber 802 or 804, respectively. In one example, each of the substrate conveyance assemblies 810 are adapted to retain eight substrates 301 and rotate the substrates 301 about a central axis of the processing chamber 802 or 804 by use of conventional rotational hardware components. The substrate conveyance assembly 810 is thus able to transfer and position the substrates 301 relative to each of the particle beams 205 found in the processing region of the processing chamber 802 or 804.

In some configurations, as illustrated in processing chamber 802 in FIG. 8, each of the substrates 301 that are disposed on the substrate conveyance assembly 810 can be rotated relative to each of the particle beams 205 by use of a substrate rotation assembly 832. The substrate rotation assembly 832 generally includes an actuator (not shown) that is configured to rotate a substrate supporting element (not shown) and substrate relative to the substrate conveyance assembly 810.

Alternately, in some configurations, as illustrated in processing chamber 804 in FIG. 8, each of the particle beams 205, which are generated by a beam extraction assembly 270, are oriented at an angle relative to the radial direction extending from the center of the processing chamber 804. In this case, when the substrates 301 are rotated about the center of the processing chamber 804 any shadowing effects created by a variability in the orientation of the features formed on the surface of the substrate 301 can be accounted for, due to differing angle that the particle beam 205 is oriented relative to the substrate 301 as it is translated below each of the beam extraction assemblies 270 by the substrate conveyance assembly 810. In one example, as illustrated in processing chamber 804 in FIG. 8, the particle beam 205 is oriented at a progressively different angle relative to the radial direction of the processing chamber, as the substrate is rotated 360 degrees by the substrate conveyance assembly 810.

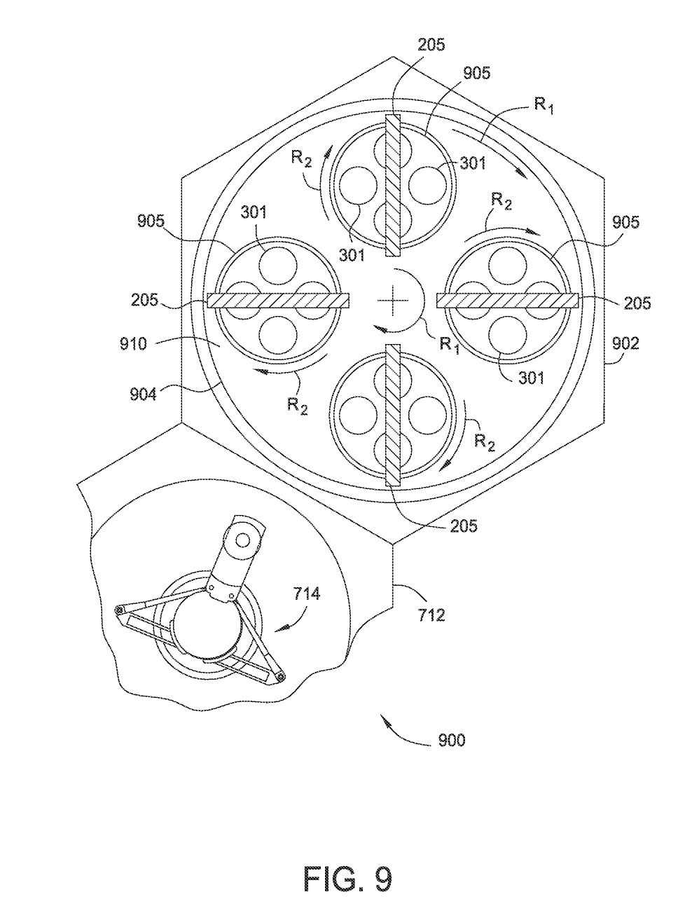

FIG. 9 is a plan view of a processing system 900 that may be used to perform one or more substrate processing steps in accordance with one embodiment of the present invention. The processing chambers 902 found in the processing system 900 is adapted to perform at least part of the plasma modification process that is described herein. The processing chamber 902 is coupled to a transfer chamber 712 and is transferrable communication with the transfer robot 714, which are described above. In this non-limiting example, the processing chamber 902 is configured to process sixteen substrates 301 at a time. As similarly discussed above, the processing system 900 also includes other processing chambers and load lock chambers that are connected to the transfer chamber 712.

In one configuration of the processing system 900, the processing chamber 902 includes a substrate conveyance assembly 904 that is configured to retain and transport a plurality of substrates 301 that are retained within the processing region of the processing chamber 902. The substrate conveyance assemblies 904 is generally adapted to retain groups of substrates 301 and rotate (R₁) the groups of substrates 301 about a central axis of the processing chamber 902 by use of conventional rotational hardware components and rotate (R₂) each group of substrates relative to the center of a substrate support 905, which supports the group of substrates, by use of conventional rotational hardware components. In some configurations, as illustrated in FIG. 9, the groups of substrates 301 are each disposed on a substrate support 905 that are disposed on a group conveyance assembly 910 can each be rotated relative to the particle beam 205 by use of rotation assembly components. The rotation assembly components generally include an actuator (not shown) that is configured to rotate the substrate support 905 relative to the substrate conveyance assembly 910. The substrate conveyance assemblies 910 is generally adapted to retain the hardware used to retain the groups of substrates 301 and rotate the groups of substrates 301 about a central axis of the processing chamber 902 by use of conventional rotational hardware components. The substrate conveyance assembly 910 is thus able to transfer and position the groups of substrates 301 relative to each of the particle beams 205 that are positioned to process substrates 301 found in the processing region of the processing chamber 902. Therefore, during processing each of the substrates 301 can be rotated and/or translated relative to a particle beam 205, which are generated by a beam extraction assembly 270. In some configurations, the surfaces that the particle beam 205 are delivered to, which includes the surfaces of the substrates 301 and any substrate supporting hardware (e.g., substrate support 905), are designed to reduce any particle contamination that would be generated by such exposure to the particle beam 205. In some cases, the exposed surface of the substrate supporting hardware is formed from a material that is similar to the material that is to be removed from the substrate (e.g., silicon, GaAs, metals) or a material that has a very low sputter yield so as to not be affect by the exposure to the particle beam 205.

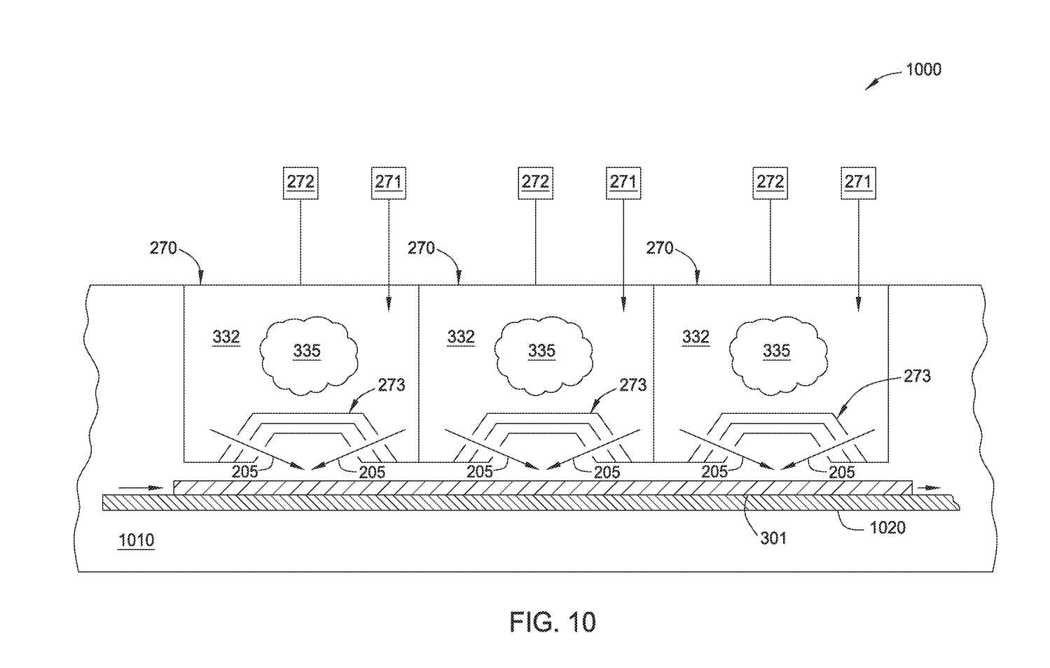

FIG. 10 is a side view of a processing chamber 1000 that may be used to perform one or more substrate processing steps in accordance with one embodiment of the present invention. The processing chamber 1000 is adapted to perform at least part of the plasma modification process that is described herein. The processing chamber 1000 generally includes one or more beam extraction assemblies 270 that are each configured to deliver one or more particle beams 205 to a surface of a substrate 301. In one example, as shown in FIG. 10, the processing chamber 1000 includes three beam extraction assemblies 270 that are each configured to deliver a particle beam 205 to a surface of the substrate 301 as it is moved relative to the beam extraction assemblies 270 by use of an actuator 1020. In this example, the beam extraction assemblies 270 are each spaced a distance from each other in a direction parallel to the transfer direction or perpendicular to a normal direction to the surface of the substrate and substrate support. The spaced apart beam extraction assemblies 270 can be used to simultaneously process different regions of the substrate at one time. In one configuration, the actuator 1020 may be a linear actuator that is configured to move the substrate 301 relative to the beam extraction assemblies 270.

As similarly discussed above, each of the beam extraction assemblies 270 within the processing chamber 1000 may be configured to provide the same type of particle beam 205 to the surface of the substrate as the substrate 301 is moved relative to the beam extraction assemblies 270 by use of an actuator 1020. In another configuration, two or more of the beam extraction assemblies 270 are adapted to provide a particle beam 205 that has some different processing characteristic, such as beam energy, beam angle (e.g., angle 210), beam angle relative to the transfer direction of the substrate, beam composition (e.g., gas ions), or other useful property to the surface of the substrate. In some cases, it may be desirable to provide a higher energy and/or higher sputter yielding particle beam 205 to the surface of the substrate by a first beam extraction assembly 270 and then a less aggressive and more smoothing planarization process is preformed by the second and/or third beam extraction assemblies 270.

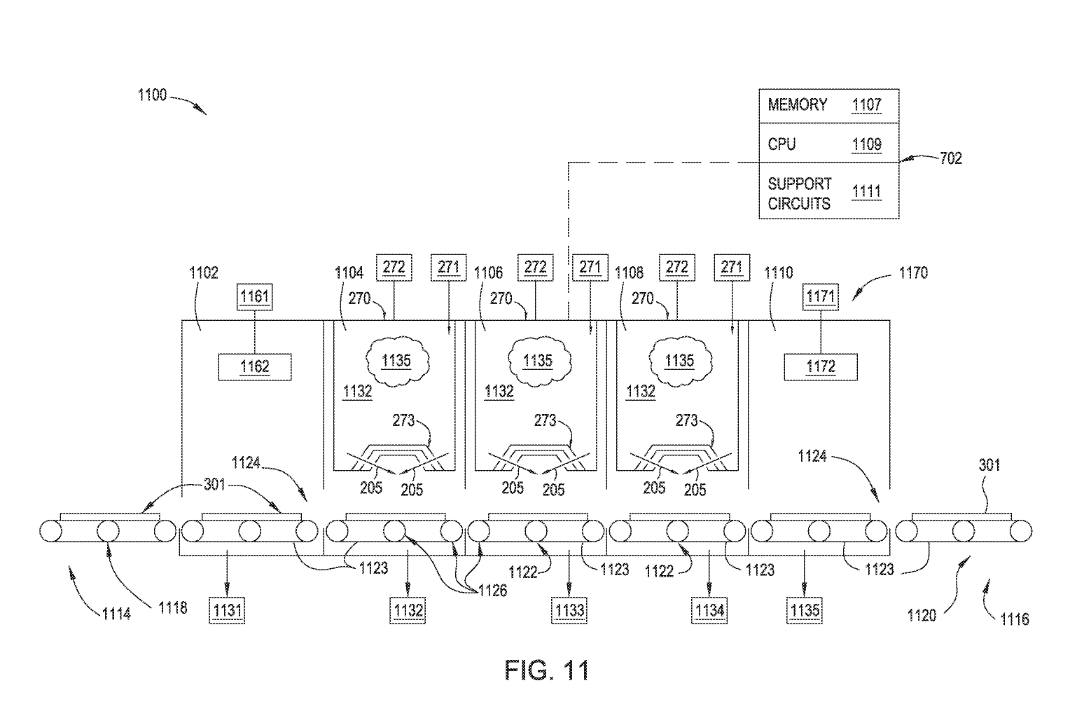

FIG. 11 is a schematic side view of one embodiment of an processing system 1100 that can be used to perform at least part of the plasma modification process described herein, wherein the processing system 1100 has various processing chambers 1102, 1104, 1106, 1108 and 1110 that are each used to perform some part of the plasma modification process on the substrates 301. The processing system 1100 has a first end 1114 where substrates 301 enter the processing system 1100, and a second end 1116 where processed substrates 301 exit the processing system 1100. At the first end 1114 an input conveyor 1118 supports and guides substrates 301 into the first chamber 1102. At the second end 1116, an exit conveyor 1120 receives substrates 301 from the final chamber 1110. A series of substrate transfer ports 1124 are provided at the entrance and exit of the apparatus and between each of the processing chambers 1102, 1104, 1106, 1108 and 1110 to allow the substrates to pass between processing chambers, while maintaining the required environment within each chamber during processing. The processing chambers 1102, 1104, 1106, 1108 and 1110 each include a gas delivery assembly that is used to control the processing environment within each chamber. The gas delivery assemblies may each include the pumping system 311 and the gas delivery source 317, which are discussed above.

In one configuration, a series of intermediate conveyors 1122 support and guide the substrates through the various processing chambers. While the conveyor system has been shown with a number of individual conveyors 1118, 1120 and 1122, a single conveyor with a continuous web of material may be used. In one configuration, the conveyors include support rollers 1126 that support and drive the web(s) of material. When individual conveyors 1118, 1120 and 1122 are used, the rollers 1126 may be mechanically driven by a common drive system (not shown) such that they are moved in unison, or individually. The various drives for the rollers 1126, ports 1124 and other system actuators are provided by control signals from a system controller 702, which as discussed above, may include memory 1107, a CPU 1109 and supporting circuits 1111. While in the embodiment illustrated in FIG. 11, has five chambers, this is not intended to be limiting as to the scope of the invention, since any number of chambers may be provided depending on the number of processes and the required equipment for each process. In one embodiment, the processing system 1100 also contains at least one additional chamber (not shown) at either end 1114, 1116 of the system that acts as a load lock to provide a buffer between the environment external to the processing chamber 300 and the processing regions of the processing chambers 1102-1110.

In one configuration of the processing system 1100, the processing chamber 1102 is adapted to perform one or more preprocessing steps on a substrate 301 before it is inserted into process chamber 1104 and the process chamber 1110 is adapted to perform one or more post-processing steps on the substrate 301 after it has been processed in at least one of the processing chambers 1104-1108. Examples, of the preprocessing or post-processing steps are further described below in conjunction with FIG. 13. In one configuration, the processing chambers 1102 and 1110 include one or more gas sources and/or energy delivery sources (e.g., sources 1161 and 1171) that are able to deliver a processing gas and/or an amount of energy to a delivery component (e.g., components 1162 and 1172), so that the preprocessing steps and post processing steps can be performed on the substrates 301.

The processing chambers 1104-1108 are each adapted to perform at least a part of the plasma modification process that is described herein. The processing chambers 1104-1108 will each generally include one or more beam extraction assemblies 270 that are configured to deliver one or more particle beams 205 to a surface of a substrate 301. In one example, the processing chambers 1104-1108 include at least one beam extraction assembly 270 that is configured to deliver a particle beam 205 to a surface of the substrate 301 as it is moved relative to the beam extraction assembly 270 by use of a conveyor 1122.

In some embodiments, each of the processes performed in each of the processing chambers 1104-1108 can be isolated from the other processing chambers due to the presence of an enclosure that surrounds the processing regions of each the processing chambers 1104-1108. In some configurations, each of the ports 1124 separating the processing regions of each of the processing chambers can be selectively closed to physically isolate the processing regions of adjacent processing chambers. In one example, a slit valve or a gate valve is mounted at each port 1124 in the processing system 1100 to selectively isolate the processing environments of adjacent processing chambers. In one configuration, each of the processing chambers 1102-1110 each include an exhaust or pumping system 1131-1135, respectively, to control the pressure and/or gas composition with the processing regions of each of the process chambers. Therefore, as similarly discussed above, each of the beam extraction assemblies 270 within the processing chambers 1104-1108 may be configured to provide the same or different type of particle beam 205 or particle beam processing environment as the substrate 301 is moved relative to the beam extraction assemblies 270 by use of the conveyors 1122.

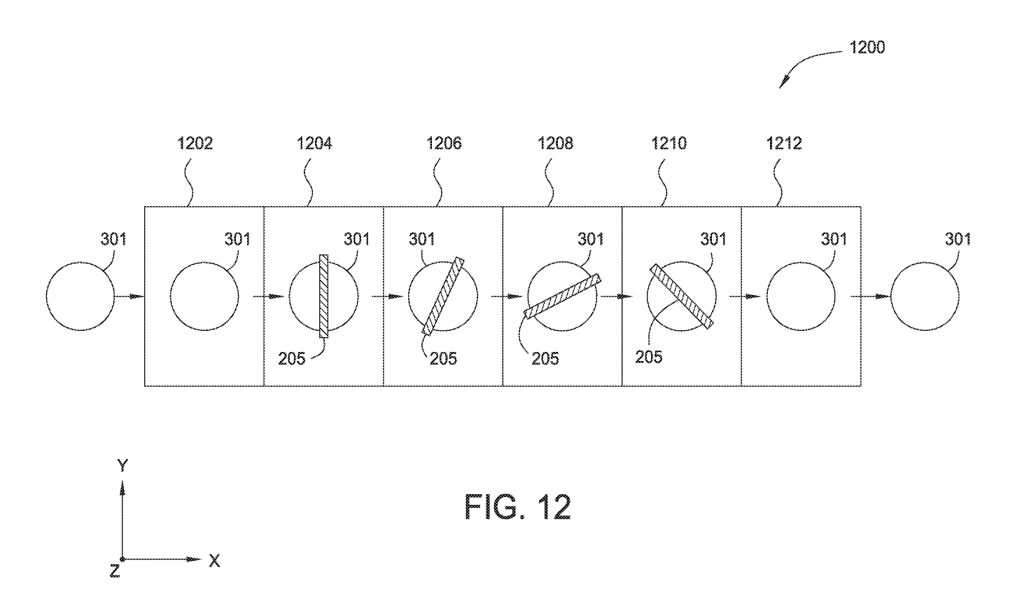

FIG. 12 is a plan view of a linear processing system 1200 that can be used to perform at least part of the plasma modification process described herein. The processing system 1200 includes processing chambers 1202, 1204, 1206, 1208, 1210 and 1212 that are each used to perform some part of the plasma modification process on the substrates 301. The process chamber 1202 and the process chamber 1212 may each include some or all of the chamber components discussed above in conjunction with processing chamber 1102 and the processing chamber 1110, respectively. The processing chambers 1204-1210 may each include some or all of the chamber components discussed above in conjunction with process chambers 1104-1108.

As illustrated in FIG. 12, the processing system 1200 includes a plurality of processing chambers 1204-1210 that are each adapted to perform at least part of the plasma modification process. In one example, each of the processing chambers 1204-1210 include one or more beam extraction assemblies (not shown) that are configured to deliver a particle beam 205 to a surface of a substrate 301. In one configuration, each of the beam extraction assemblies are adapted to provide a particle beam 205 that has some different processing characteristic to the surface of the substrate. In one example, each of the beam extraction assemblies are adapted to provide a particle beam 205 that has a different beam angle relative to the transfer direction (i.e., X-direction) of the substrate. By varying the angular orientation of the particle beams 205 provided to the surface of the substrate in each process chamber, any shadowing effects created by the orientation of the features formed on the surface of the substrate can be reduced or minimized, which can improve the uniformity of the planarized surface of the substrate that was processed in the processing system 1200.

### Plasma Modification Process Examples

FIG. 13 is a block diagram illustrating a plasma modification processing sequence that may be performed on a substrate in one or more of the process chambers and/or processing system described above. In one embodiment, the processing sequence 1300 may all be performed in a processing system that is similar to the processing systems 700, 800, 900, 1000, 1100 or 1200, which are discussed above in conjunction with FIGS. 7-12. It is noted that the processing sequence depicted in FIG. 13 is only used as an example of a plasma modification process flow and thus is not intended to be limiting as to the scope of the invention disclosed herein. Additionally steps may be added in between any of the steps depicted in FIG. 13 as needed to improve the plasma modification process results. Similarly, one or more steps depicted herein may also be eliminated as needed.

In one embodiment, the processing sequence 1300, starts at step 1302 in which an optional pre-planarization process is performed on a surface of a substrate. In general, the optional pre-planarization process step 1302 may include the use of a chemical mechanical polishing (CMP) process to remove at least a portion of the material disposed on the surface of the substrate prior to performing the plasma modification process step, or step 1304 on the substrate. The use of an initial CMP process step prior to performing plasma modification processing step 1304 may be useful to help remove some of the variation in the height of the features formed on the surface of an un-planarized substrate. In this case, the subsequent plasma modification processing step 1304 may only provide a fine planarization of the surface of the substrate, or in other words a “fine polishing” of the surface of the substrate.

In one embodiment of the processing sequence 1300, the optional step 1302 may alternately or additionally include a wet or dry chemical cleaning process that is used to remove a portion of the surface of the substrate prior to performing the plasma modification processing step 1304. In one example, an oxide layer or a contaminated layer may be removed from the surface of the substrate by use of one or more reactive species, such as delivering an etching gas or a cleaning solution to a surface of the substrate, to remove a portion of the material from the surface of the substrate.

Next, in step 1304, a plasma modification process is performed on an exposed surface of a substrate to make the outer surface of the substrate relatively flat and/or smooth. As discussed above, the step 1304 may include the delivery of an energetic particle beam that includes a spatially localized group of energetic particles that are directed towards a surface of a substrate for a desired period of time. The plasma modification process may include the simultaneous and/or sequential delivery of a plurality of particle beams 205 to a surface of the substrate. Each of the delivered particle beams may have different processing characteristic, such as beam energy, beam angle, beam composition (e.g., gas ions), or other useful property.

In some embodiments, step 1304 includes the delivery of at least one energetic particle beam to a surface of a substrate in multiple sequential processing steps to planarize the surface of the substrate. As noted above, the multiple sequential processing steps may be performed in a single plasma modification processing chamber or in multiple plasma modification processing chambers. Also, as discussed above, the particle beam modification process performed in step 1304 may include the use of physical and/or chemical material planarization processes performed in a single process step or in one or more of the multiple sequential processing steps.

Referring to FIGS. 3 and 13, step 1304 may include, for example, the following sub-process steps. First, one or more gas sources 341 deliver one or more inert and/or reactive gases to the plasma generation region 332. The plasma generation source 272 then delivers an amount of electromagnetic energy to the delivered process gas to form the plasma in the plasma generation region 332. The electrode assembly 273 and system controller 390 are then used to extract ions found within the plasma generation region 332 to form, control and deliver one or more particle beams 205, which each have desirable particle beam properties, to a surface of a substrate 301 that is disposed on a substrate support within the processing region 310 of the processing chamber 300. In some configurations of step 1304, the system controller 390, pumping system 311 and gas delivery source 317 are used in combination to control the processing environment within the processing region 310. The gas delivery source 317 and pumping system 311 are typically used to control the pressure and/or gas composition of the processing environment found within the processing region 310. In some cases, the processing environment may include either an inert and/or substrate etchant containing gas to promote the plasma modification process. During step 1304, the substrate and/or the one or more energetic particle beams 205 may be moved relative to each other to enhance the plasma modification process. Next, after the system controller 390 receives a signal from the endpoint monitoring system 376, or by simply reaching a desired time that the substrate is exposed to the one or more energetic particle beams 205, the plasma modification process performed in step 1304 is stopped.

Next, in step 1306, an optional cleaning process is performed on substrate after step 1304 has been performed. In this step, the substrate is cleaned to remove any undesirable materials left over from the prior processing steps. In some configurations, step 1306 includes the delivery of a cleaning gas (e.g., dry cleaning process) to a surface of the substrate in a processing chamber that is disposed on a processing system (e.g., processing systems 700, 800, 900, 1000, 1100 or 1200) that contains a processing chamber that is adapted to perform step 1304. In one example, step 1306 may include the use of a reactive ion etching (RIE) or a plasma assisted dry etching process that is provided to a surface of the substrate to clean and/or remove any residual contamination found on the surface of the substrate. Alternately, step 1306 may include an ex-situ cleaning process that includes the delivery of a wet cleaning solution to a surface of the substrate to remove any undesirable materials from the surface of the substrate. In this case, the substrate may be cleaned using a wet cleaning process in which a cleaning solution, such as a HF-last type cleaning solution, ozonated water cleaning solution, hydrofluoric acid (HF) and hydrogen peroxide (H₂O₂) solution, DI water, or other suitable cleaning solution. In some embodiments of the processing sequence 1300, step 1306 may be performed after performing step 1308, which is discussed below.

Next, at step 1308, an optional post-planarization process is performed on the substrate after step 1304 has been performed. In one configuration, the optional post-planarization process step 1308 may include the use of a chemical mechanical polishing (CMP) process to remove at least a portion of the material disposed on the surface of the substrate after performing step 1304 on the substrate. The CMP process in this case may be useful to help remove and further planarize some of the features formed on the surface of the substrate. In this case, the plasma modification process completed in step 1304 may provide a rapid and/or partial planarization of the surface of the substrate, and the post-planarization process step 1308 provides the final planarization clean-up of the surface of the substrate. The CMP type post-planarization process step may be used to remove any islands or other unwanted material left on the surface of the substrate leftover from the previous plasma modification process step 1304.

In one embodiment of the processing sequence 1300, the optional step 1308 may alternately or additionally include a deposition process step that is used to “cap” the surface of the substrate after performing the plasma modification processing step 1304. In one example, deposition process may include the deposition of a conductive (e.g., titanium layer, tantalum layer), a semiconductive (e.g., silicon, GaAs, III-V layer) or a dielectric layer (e.g., SiO₂, SiN) over the surface of the previously processed surface of the substrate. In some configurations, step 1308 includes the formation of a layer on a surface of the substrate in a processing chamber that is disposed in a processing system (e.g., processing systems 700, 800, 900, 1000, 1100 or 1200) that contains a processing chamber that is adapted to perform step 1304. In some examples, the deposition process may be completed by performing a deposition process in a processing chamber that is configured to perform a plasma enhanced chemical vapor deposition (PECVD) process, low pressure chemical vapor deposition (LPCVD) process, hot wire chemical vapor deposition (HWCVD) process, atomic layer deposition (ALD) process, physical vapor deposition (PVD) process, and/or other similar deposition process.

Embodiments of the disclosure provided herein may thus provide a processing sequence 1300 that includes steps 1302 and 1304, which are discussed above. Some embodiments of the disclosure may provide a processing sequence 1300 that includes steps 1302, 1304 and 1308. Some embodiments of the disclosure may also provide a processing sequence 1300 that includes steps 1304 and 1308. Some embodiments of the disclosure may also provide a processing sequence 1300 that includes steps 1304 and 1306. Some embodiments of the disclosure may also provide a processing sequence 1300 that includes steps 1304, 1306 and 1308. Some embodiments of the disclosure may also provide a processing sequence 1300 that includes steps 1304, 1308 and 1306, which are performed in that processing order. Some embodiments of the disclosure may also provide a processing sequence 1300 that includes steps 1302, 1304, 1306 and 1308, where steps 1306 and 1308 are performed in any desirable processing order. Some embodiments of the disclosure may also provide a processing sequence 1300 that only includes step 1304.

While the foregoing is directed to embodiments of the present invention, other and further embodiments of the invention may be devised without departing from the basic scope thereof, and the scope thereof is determined by the claims that follow.

1. An apparatus for modifying a surface of a substrate, comprising:
a substrate support having a substrate supporting surface, wherein a first direction is perpendicular to the substrate supporting surface;
a first beam extraction assembly configured to simultaneously generate:
a first particle beam that exits the first beam extraction assembly in a second direction, wherein the first particle beam is directed towards the substrate supporting surface and the second direction is at a first grazing angle relative to the first direction; and
a second particle beam that exits the first beam extraction assembly in a third direction, wherein the second particle beam is directed towards the substrate supporting surface and the third direction is at the first grazing angle or a second grazing angle relative to the first direction; and
an actuator that is configured to translate the substrate supporting surface relative to the first and the second particle beams.

2. The apparatus of claim 1, wherein the first grazing angle or the second grazing angle are between about 70 and about 80 degrees.

3. The apparatus of claim 1, further comprising:
a second beam extraction assembly that is positioned a distance in a fourth direction from the first beam extraction assembly, wherein the fourth direction is perpendicular to the first direction, and the second beam extraction assembly is configured to simultaneously generate:
a third particle beam that exits the second beam extraction assembly in a fifth direction, wherein the third particle beam is directed towards the substrate supporting surface and the fifth direction is at a third grazing angle relative to the first direction; and
a fourth particle beam that exits the second beam extraction assembly in a sixth direction, wherein the fourth particle beam is directed towards the substrate supporting surface and the sixth direction is at the third grazing angle or a fourth grazing angle relative to the first direction,
wherein the actuator that is configured to translate the substrate supporting surface of the substrate support relative to the third and fourth particle beams.

4. The apparatus of claim 1, wherein the first beam extraction assembly further comprises a first steering electrode that can be biased by a first power source, wherein altering the bias applied by the first power source changes the magnitude of the first grazing angle.

5. The apparatus of claim 1, further comprises:
an electric field control assembly that comprises a control element, which is positioned between the first beam extraction assembly and the substrate support.

6. The apparatus of claim 1, further comprises:
an RF power source; and
a support electrode that is positioned to generate a plasma in a processing region defined between the first beam extraction assembly and the substrate support when the support electrode is biased by the RF power source.

7. The apparatus of claim 1, wherein the first beam extraction assembly further comprises:
a first electrode having a first aperture that is positioned to receive charged particles formed in a plasma generation region of the first beam extraction assembly;
a second electrode having a second aperture that is positioned to receive a flow of the charged particles that pass through the first aperture, wherein the flow of the charged particles form at least part of the first particle beam;
a field shaping power source is configured to apply a bias to a control element disposed between the first beam extraction assembly and the substrate support; and
a system controller that is configured to adjust an electrical bias applied by the field shaping power source during processing.

8. A method of planarizing a surface of a substrate in a processing region of a processing chamber, comprising:
delivering a first particle beam from a beam extraction assembly towards a substrate disposed on a substrate supporting surface of a substrate support, wherein the delivered first particle beam is provided in a first direction that is at a first grazing angle relative to a second direction which is perpendicular to the substrate supporting surface;
delivering a second particle beam from the beam extraction assembly towards the substrate supporting surface, wherein the delivered second particle beam is provided in a third direction that is at the first grazing angle or a second grazing angle relative to the second direction; and
moving the substrate relative to the first and second particle beams, or moving the first and second particle beams relative to the substrate, to reduce the non-planarity of a non-planar surface formed on the substrate.

9. The method of claim 8, further comprises:
delivering a etching gas to a processing region in which the substrate is disposed while substrate is moved relative to the delivered first and second particle beams, wherein the etching gas comprises a gas selected from the group of chlorine (Cl₂), fluorine (F₂), bromine (Br₂) and iodine (I₂), and ammonia (NH₃).

10. The method of claim 8, further comprises:
polishing the non-planar surface of the substrate prior to positioning the substrate to receive the at least a portion of the formed particle beam, wherein polishing the non-planar surface comprises performing a chemical mechanical planarization process.

11. The method of claim 8, wherein delivering the first particle beam towards the substrate further comprises:
delivering electromagnetic energy to a process gas that is disposed in a plasma generation region of a processing chamber, wherein delivering the electromagnetic energy ionizes at least a portion of the process gas disposed in the plasma generation region;
biasing a first electrode that has a first aperture formed therein, wherein biasing the first electrode causes at least a portion of the charged particles to pass through the first aperture;
biasing a second electrode that has a second aperture formed therein, wherein biasing the second electrode causes the portion of the charged particles passing through the first aperture to be accelerated as the portion of the charged particles passes between the first aperture and the second aperture, wherein the portion of the charged particles passing through second aperture forms at least part of the formed first particle beam; and
applying a bias to a control element, wherein the control element is positioned between the beam extraction assembly and the substrate, and biasing the control element is configured to alter an electric field generated by separately applying a bias to the first electrode or the second electrode.

12. The method of claim 11, further comprises:
adjusting the position of the second aperture relative to the first aperture to alter the path of the formed particle beam.

13. An system for planarizing a surface of a substrate, comprising:
a transfer chamber having a transfer region;
a first process chamber that is coupled to the transfer chamber, wherein the first process chamber comprises:
a substrate support having a substrate supporting surface, wherein a first direction is perpendicular to the supporting surface;
a first beam extraction assembly configured to simultaneously generate:
a first particle beam that exits the first beam extraction assembly in a second direction, wherein the first particle beam is directed towards the substrate supporting surface and the second direction is at a first grazing angle relative to the first direction; and
a second particle beam that exits the first beam extraction assembly in a third direction, wherein the second particle beam is directed towards the substrate supporting surface and the third direction is at the first grazing angle or a second grazing angle relative to the first direction;
an actuator that is configured to translate the substrate supporting surface of the substrate support relative to the first and the second particle beams;
a second process chamber that is coupled to the transfer chamber, wherein the second process chamber configured to deposit a layer on the substrate; and
a substrate transfer robot disposed in the transfer region, and configured to load and unload substrates disposed in the first processing chamber and the second processing chamber.

14. The system of claim 13, wherein the first process chamber further comprises:
a second beam extraction assembly that is positioned a distance in a fourth direction from the first beam extraction assembly, wherein the fourth direction is perpendicular to the first direction, and the second beam extraction assembly is configured to simultaneously generate:
a third particle beam that exits the second beam extraction assembly in a fifth direction, wherein the third particle beam is directed towards the substrate supporting surface and the fifth direction is at a third grazing angle relative to the first direction;
a fourth particle beam that exits the second beam extraction assembly in a sixth direction, wherein the fourth particle beam is directed towards the substrate supporting surface and the sixth direction is at the third grazing angle or a fourth grazing angle relative to the first direction; and
wherein the actuator that is configured to translate the substrate supporting surface of the substrate support relative to the third and fourth particle beams.

15. The system of claim 13, wherein the first beam extraction assembly further comprises a first steering electrode that can be biased by a first power source, wherein altering the bias applied by the first power source changes the magnitude of the first grazing angle.

16. The system of claim 13, further comprises:
an electric field control assembly that comprises a control element, which is positioned between the first beam extraction assembly and the substrate support.

17. The system of claim 13, further comprises:
an RF power source; and
a support electrode that is positioned to generate a plasma in a processing region defined between the first beam extraction assembly and the substrate support when the support electrode is biased by the RF power source.

18. The system of claim 13, wherein the first beam extraction assembly further comprises:
a first electrode having a first aperture that is positioned to receive charged particles formed in a plasma generation region of the first beam extraction assembly;
a second electrode having a second aperture that is positioned to receive a flow of the charged particles that pass through the first aperture, wherein the flow of the charged particles form at least part of the first particle beam;
a field shaping power source is configured to apply a bias to a control element disposed between the first beam extraction assembly and the substrate support;
a system controller that is configured to adjust an electrical bias applied by the field shaping power source during processing; and
a third electrode having a third aperture that is positioned to receive the flow of charged particles that was received by the second aperture.
